(19) United States
(12) Patent Application Publication
(10) Pub. No.: US 2020/0343156 A1
(43) Pub. Date: Oct. 29, 2020

(54) HEAT DISSIPATION STRUCTURE FOR SEMICONDUCTOR DEVICE, METHOD OF MANUFACTURING THE SAME, AND AMPLIFIER

(71) Applicant: FUJITSU LIMITED, Kawasaki-shi (JP)

(72) Inventor: NAOYA OKAMOTO, Isehara (JP)

(73) Assignee: FUJITSU LIMITED, Kawasaki-shi (JP)

(21) Appl. No.: 16/852,601

(22) Filed: Apr. 20, 2020

(30) Foreign Application Priority Data
Apr. 23, 2019 (JP) 2019-081827

(51) Int. Cl. H01L 23/367; H01L 23/373; H01L 21/48

(52) U.S. Cl. CPC H01L 23/367; H01L 21/4882; H01L 23/3732

(57) ABSTRACT

A heat dissipation structure for a semiconductor device, the structure includes: a heat sink provided under a rear surface side of a substrate included in a semiconductor device; and a front heat spreader coupled to metal wiring provided over an electrode disposed on a front surface side of the semiconductor device and a metal unit provided at least partially over an outer peripheral portion of the front surface side of the semiconductor device.

### CROSS-REFERENCE TO RELATED APPLICATION

This application is based upon and claims the benefit of priority of the prior Japanese Patent Application No. 2019-81827, filed on Apr. 23, 2019, the entire contents of which are incorporated herein by reference.

### FIELD

The embodiments discussed herein are related to a heat dissipation structure for a semiconductor device, a method of manufacturing the heat dissipation structure for a semiconductor device, and an amplifier.

### BACKGROUND

Examples of a heat dissipation structure for a semiconductor device include a structure in which a heat sink is provided under a rear surface side of a substrate included in a semiconductor device (see, for example, FIG. 36).

In such a heat dissipation structure, in some cases, a diamond heat spreader is provided between the substrate and the heat sink (see, for example, FIG. 38).

Examples of related art include Japanese Laid-open Patent Publication No. 10-284657 and International Publication Pamphlet Nos. WO 2007141851, WO 2012132709, and WO 2015193153.

### SUMMARY

According to an aspect of the embodiments, a heat dissipation structure for a semiconductor device, the structure includes: a heat sink provided under a rear surface side of a substrate included in a semiconductor device; and a front heat spreader coupled to metal wiring provided over an electrode disposed on a front surface side of the semiconductor device and a metal unit provided at least partially over an outer peripheral portion of the front surface side of the semiconductor device.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a sectional view illustrating a heat dissipation structure for a semiconductor device according to a first embodiment;

FIG. 2 is a sectional view explaining heat dissipation in the heat dissipation structure for a semiconductor device according to the first embodiment;

FIG. 3 is a sectional view illustrating a modification of the heat dissipation structure for a semiconductor device according to the first embodiment;

FIG. 4 is a sectional view explaining heat dissipation in the modification of the heat dissipation structure for a semiconductor device according to the first embodiment;

FIG. 5 is a diagram explaining an effect of the heat dissipation structure for a semiconductor device according to the first embodiment;

FIG. 6 is a sectional view illustrating a heat dissipation structure for a semiconductor device of a comparative example;

FIG. 7 is a sectional view illustrating a heat dissipation structure for a semiconductor device of a comparative example;

FIG. 8 is a sectional view illustrating a heat dissipation structure for a semiconductor device of a comparative example;

FIG. 9 is a sectional view illustrating a heat dissipation structure for a semiconductor device of a comparative example;

FIG. 10 is a diagram explaining the effect of the heat dissipation structure for a semiconductor device according to the first embodiment;

FIG. 11 is a sectional view explaining a method of manufacturing a first configuration example of the heat dissipation structure for a semiconductor device according to the first embodiment;

FIG. 12 is a sectional view explaining the method of manufacturing the first configuration example of the heat dissipation structure for a semiconductor device according to the first embodiment;

FIG. 13 is a sectional view explaining the method of manufacturing the first configuration example of the heat dissipation structure for a semiconductor device according to the first embodiment;

FIG. 14 is a sectional view explaining the method of manufacturing the first configuration example of the heat dissipation structure for a semiconductor device according to the first embodiment;

FIG. 15 is a sectional view explaining the method of manufacturing the first configuration example of the heat dissipation structure for a semiconductor device according to the first embodiment;

FIG. 16 is a sectional view explaining the method of manufacturing the first configuration example of the heat dissipation structure for a semiconductor device according to the first embodiment;

FIG. 17 is a sectional view explaining the configuration and the method of manufacturing the first configuration example of the heat dissipation structure for a semiconductor device according to the first embodiment;

FIG. 18 is a plan view (top view) explaining the configuration and the method of manufacturing the first configuration example of the heat dissipation structure for a semiconductor device according to the first embodiment;

FIG. 19 is a sectional view illustrating a configuration of a modification of the first configuration example of the heat dissipation structure for a semiconductor device according to the first embodiment;

FIG. 20 is a sectional view explaining a method of manufacturing a second configuration example of the heat dissipation structure for a semiconductor device according to the first embodiment;

FIG. 21 is a sectional view explaining the method of manufacturing the second configuration example of the heat dissipation structure for a semiconductor device according to the first embodiment;

FIG. 22 is a sectional view explaining the method of manufacturing the second configuration example of the heat dissipation structure for a semiconductor device according to the first embodiment;

FIG. 23 is a sectional view explaining the method of manufacturing the second configuration example of the heat dissipation structure for a semiconductor device according to the first embodiment;

FIG. 24 is a sectional view explaining the configuration and the method of manufacturing the second configuration example of the heat dissipation structure for a semiconductor device according to the first embodiment;

FIG. 25 is a sectional view illustrating a configuration of a modification of the second configuration example of the heat dissipation structure for a semiconductor device according to the first embodiment;

FIG. 26 is a sectional view explaining a method of manufacturing a third configuration example of the heat dissipation structure for a semiconductor device according to the first embodiment;

FIG. 27 is a sectional view explaining the method of manufacturing the third configuration example of the heat dissipation structure for a semiconductor device according to the first embodiment;

FIG. 28 is a sectional view explaining the method of manufacturing the third configuration example of the heat dissipation structure for a semiconductor device according to the first embodiment;

FIG. 29 is a sectional view explaining the method of manufacturing the third configuration example of the heat dissipation structure for a semiconductor device according to the first embodiment;

FIG. 30 is a sectional view explaining the method of manufacturing the third configuration example of the heat dissipation structure for a semiconductor device according to the first embodiment;

FIG. 31 is a sectional view explaining the configuration and the method of manufacturing the third configuration example of the heat dissipation structure for a semiconductor device according to the first embodiment;

FIG. 32 is a sectional view illustrating a configuration of a modification of the third configuration example of the heat dissipation structure for a semiconductor device according to the first embodiment;

FIG. 33 is a sectional view illustrating a configuration of a modification of the third configuration example of the heat dissipation structure for a semiconductor device according to the first embodiment;

FIG. 34 is a sectional view illustrating a configuration of a modification of the third configuration example of the heat dissipation structure for a semiconductor device according to the first embodiment;

FIG. 35 is a diagram illustrating a configuration of an amplifier according to a second embodiment;

FIG. 36 is a sectional view illustrating the related-art heat dissipation structure for a semiconductor device;

FIG. 37 is a sectional view explaining heat dissipation in the related-art heat dissipation structure for the semiconductor device;

FIG. 38 is a sectional view illustrating the related-art heat dissipation structure for a semiconductor device; and

FIG. 39 is a sectional view explaining heat dissipation in the related-art heat dissipation structure for a semiconductor device.

### DESCRIPTION OF EMBODIMENTS

However, as the output of the semiconductor device increases, the amount of heat generation increases. Thus, with the related-art heat dissipation structure as described above, it becomes difficult to improve the performance. It is an object of the embodiments to allow heat to be dissipated more efficiently than with the related-art heat dissipation structure.

Hereinafter, a heat dissipation structure for a semiconductor device, a method of manufacturing the heat dissipation structure for a semiconductor device, and an amplifier according to embodiments of the present disclosure will be described with reference to the drawings.

### First Embodiment

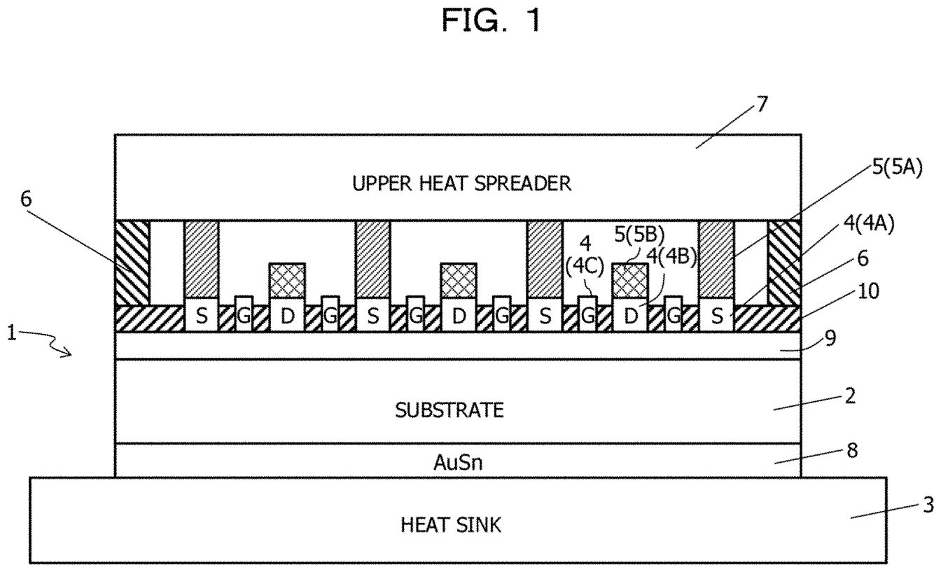

First, the heat dissipation structure for a semiconductor device and the method of manufacturing the heat dissipation structure for a semiconductor device according to a first embodiment are described with reference to FIGS. 1 to 34.

The heat dissipation structure for a semiconductor device according to the present embodiment may be applied to, for example, a heat dissipation structure for a high-power high-frequency semiconductor device used for long distance radio wave application fields such as radar, radio communication, and microwave power transmission, for example, a heat dissipation structure for a high-power semiconductor device including a GaN-based high electron mobility transistor (GaN HEMT).

The high-power high-frequency semiconductor device is also referred to as a high-power semiconductor device or a high-power device.

As illustrated in FIG. 1, the heat dissipation structure for a semiconductor device according to the present embodiment has a structure in which the heat dissipation structure for a semiconductor device includes a heat sink 3 disposed under a rear surface side of a substrate 2 included in a semiconductor device 1. This heat dissipation structure for a semiconductor device further includes an upper heat spreader (front heat spreader) 7 coupled to metal wiring 5 provided over electrodes 4 disposed on a front surface side of the semiconductor device 1 and a metal unit 6 provided over an outer peripheral portion of the front surface side of the semiconductor device 1.

In this case, the metal unit 6 is provided over a front surface of the semiconductor device 1. The metal unit 6 is provided not outside the semiconductor device 1 (outside; outside a chip) but inside the semiconductor device 1 (inside; inside a chip).

The semiconductor device 1 includes an epitaxial layer 9 over the substrate 2 and source electrodes 4A, drain electrodes 48, and gate electrodes 4C over the epitaxial layer 9.

As the metal wiring 5, source wiring 5A is provided over the source electrodes 4A and drain wiring 5B is provided over the drain electrodes 4B.

The semiconductor device 1 is structured such that a front surface of the epitaxial layer 9 is covered with an insulating film (for example, a SiN film) 10.

The semiconductor device 1 includes a HEMT structure (transistor structure) that includes, for example, an electron supply layer, an electron transit layer, and the like.

The heat sink 3 is joined to a rear surface of the substrate 2 included in the semiconductor device 1 with, for example, solder 8 such as AuSn interposed between the heat sink 3 and the rear surface of the substrate 2.

The upper heat spreader 7 is joined to the metal wiring 5 (source wiring 5A herein) and the metal unit 6. For example, the upper heat spreader 7 is joined to the front surface of the semiconductor device 1 with the metal wiring 5 (source wiring 5A herein) and the metal unit 6 interposed between the upper heat spreader 7 and the front surface of the semiconductor device 1. Thus, heat may be efficiently dissipated.

The substrate is also referred to as a semiconductor substrate. The rear surface side of the substrate included in the semiconductor device is also referred to as a rear surface side of the semiconductor device or a rear surface side of the semiconductor substrate. The front surface side of the semiconductor device is also referred to as a front surface side of the semiconductor substrate. Since the front heat spreader is provided over an upper portion of the semiconductor device, the front heat spreader is also referred to as the upper heat spreader. The semiconductor device is also referred to as a semiconductor chip, a chip, or a device chip. The outer peripheral portion of the semiconductor device is also referred to as a chip outer periphery.

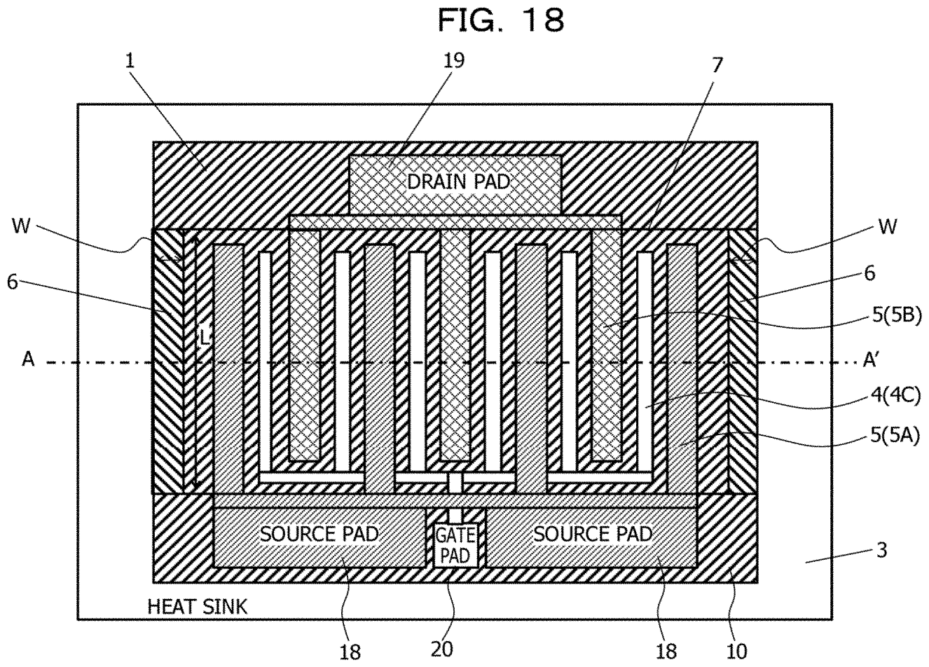

Herein, the metal unit 6 is provided over a first part and a second part opposite the first part of the outer peripheral portion of the front surface side of the semiconductor device 1 (see, for example, FIG. 18).

For example, the metal unit 6 is provided over both the one side and the other side opposite the one side of the outer peripheral portion of the front surface side of the semiconductor device 1.

In this case, the metal unit 6 is joined to both the one side and the other side opposite the one side of the upper heat spreader 7 (see, for example, FIG. 18).

Although the metal unit 6 is separated and provided at two positions over both sides of the outer peripheral portion of the front surface side of the semiconductor device 1 herein, this is not limiting. For example, the metal unit 6 may be provided at a single position or at three or more positions. The metal unit 6 may be provided at other positions over the outer peripheral portion or integrally formed into a ring shape over the entirety of the outer peripheral portion. As described above, it is sufficient that the metal unit 6 be provided at least partially over the outer peripheral portion of the front surface side of the semiconductor device 1.

Preferably, the thermal conductivity of the upper heat spreader 7 is 200 W/mK or greater. This may allow sufficient dissipation of heat as will be described later.

Preferably, the upper heat spreader 7 is formed of a material selected from the group consisting of CuMo, CuW, Al, GaN, Cu, Au, Ag, AlN, SiC, graphite, and diamond.

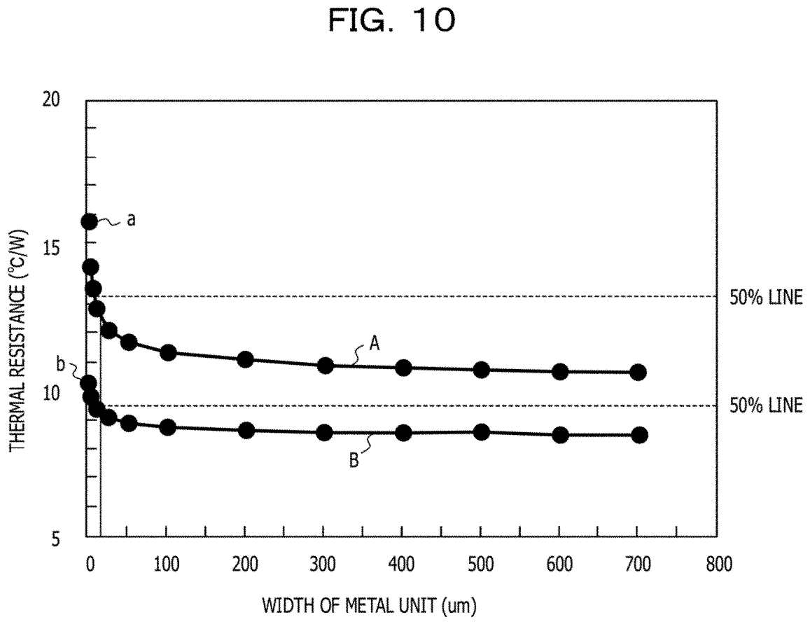

Preferably, the width of the metal unit 6 (for example, see reference sign W in FIG. 18) is 10 μm or greater (for example, see FIG. 10). For example, preferably, the width of the metal unit 6 coupled to the upper heat spreader 7 is 10 μm or greater. This may allow sufficient dissipation of heat as will be described later.

The width of the metal unit 6 is the distance from a side close to heat generation sources that are included in a transistor region (HEMT region) to a side far from the heat generation sources (see, for example, FIG. 18). Although the length of the metal unit 6 (see, for example, reference sign L in FIG. 18) is the same as that of the upper heat spreader 7, the length of the metal unit 6 may be greater than that of the upper heat spreader 7.

Preferably, the electrodes 4 include the source electrodes 4A. Preferably, the metal wiring 5 is the source wiring 5A provided over the source electrodes 4A. For example, preferably, the metal wiring 5 coupled to the upper heat spreader 7 is the source wiring 5A provided over the source electrodes 4A. Thus, the ground potential may be stabilized and inductance may be reduced.

Preferably, the metal wiring 5 and the metal unit 6 are formed of the same type of metal. This may allow, as will be described later, the metal wiring 5 and the metal unit 6 to be fabricated at the same time. This may facilitate the fabrication of the metal wiring 5 and the metal unit 6.

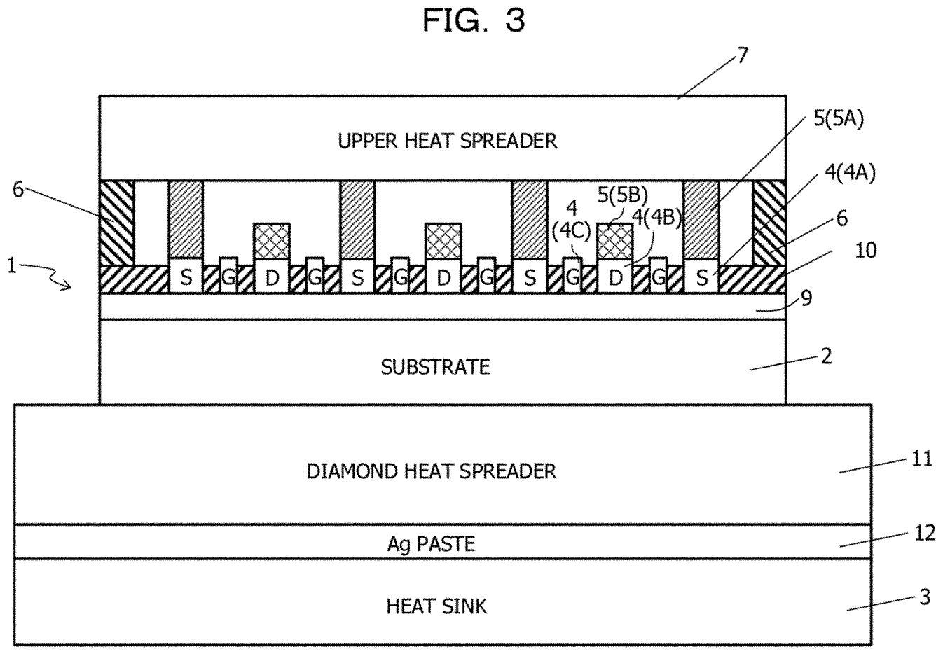

For example, preferably, a diamond heat spreader 11 is provided between the substrate 2 and the heat sink 3 as illustrated in FIG. 3. For example, preferably, the diamond heat spreader 11 having a very high thermal conductivity is provided under the rear surface side of the semiconductor substrate 2. Thus, heat may be more efficiently dissipated.

For example, the diamond heat spreader 11 may be joined to the rear surface side of the semiconductor substrate 2, and the heat sink 3 may be joined to a rear surface side of the diamond heat spreader 11 with, for example, Ag paste 12 or the like interposed between the rear surface side of the diamond heat spreader 11 and the heat sink 3.

Thus, the diamond heat spreader 11 is provided under the rear surface side of the semiconductor substrate 2. The diamond heat spreader 11 is provided between the substrate 2 (rear surface of the substrate) and the heat sink 3.

The diamond heat spreader 11, which is provided under a lower portion of the semiconductor device 1, is also referred to as a lower heat spreader.

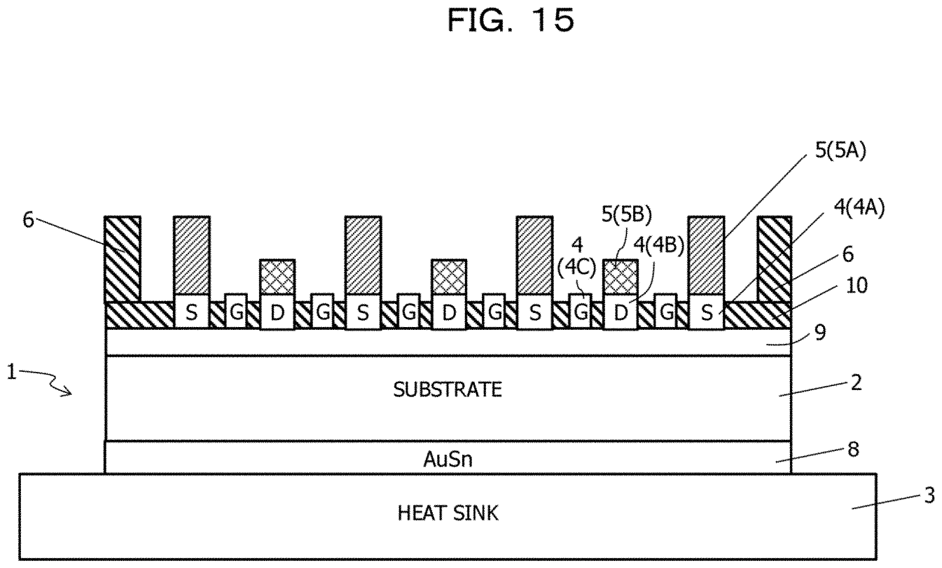

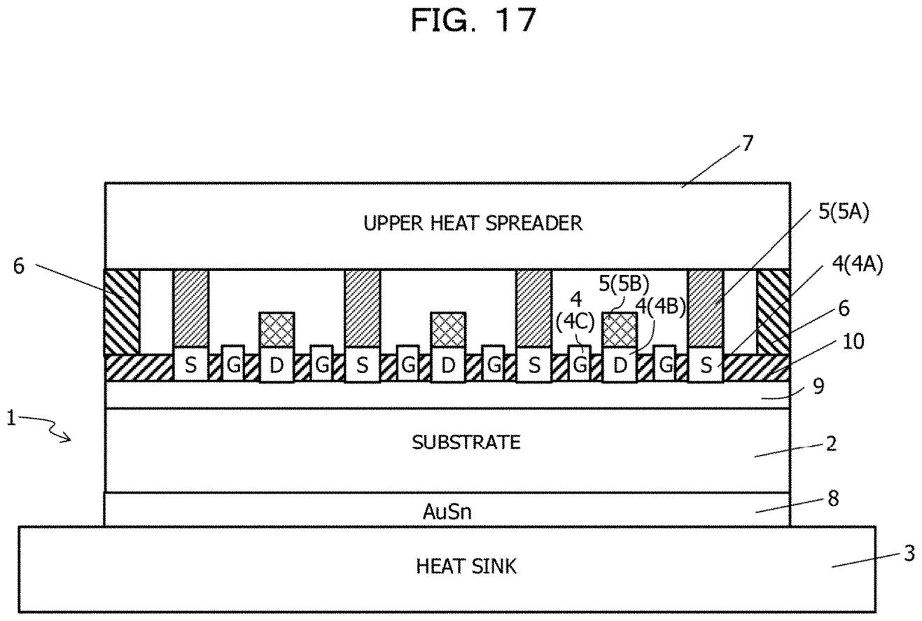

A method of manufacturing the heat dissipation structure for the semiconductor device 1 configured as described above, for example, a method of manufacturing the heat dissipation structure for the semiconductor device 1 according to the present embodiment includes the following steps: a step of providing the heat sink 3 under the rear surface side of the substrate 2 included in the semiconductor device 1 (see, for example FIGS. 15, 22, and 30); and a step of providing the upper heat spreader (front heat spreader) 7 so as to be coupled to the metal wiring 5 provided over the electrodes 4 disposed on the front surface side of the semiconductor device 1 and coupled to the metal unit 6 provided at least partially over the outer peripheral portion of the front surface side of the semiconductor device 1 (see, for example, FIGS. 17, 19, 24, 25, 31, and 32). Thus, heat may be efficiently dissipated.

In the step of providing the upper heat spreader (front heat spreader) 7, preferably, the upper heat spreader 7 is coupled to the metal wiring 5 and the metal unit 6 by room-temperature joining. Thus, even when the distance between wires of the metal wiring 5 is small, the upper heat spreader 7 may be joined without deformation of the wires. Thus, even when the distance between wires of the metal wiring 5 is small, the upper heat spreader 7 may be joined without deformation of the wires.

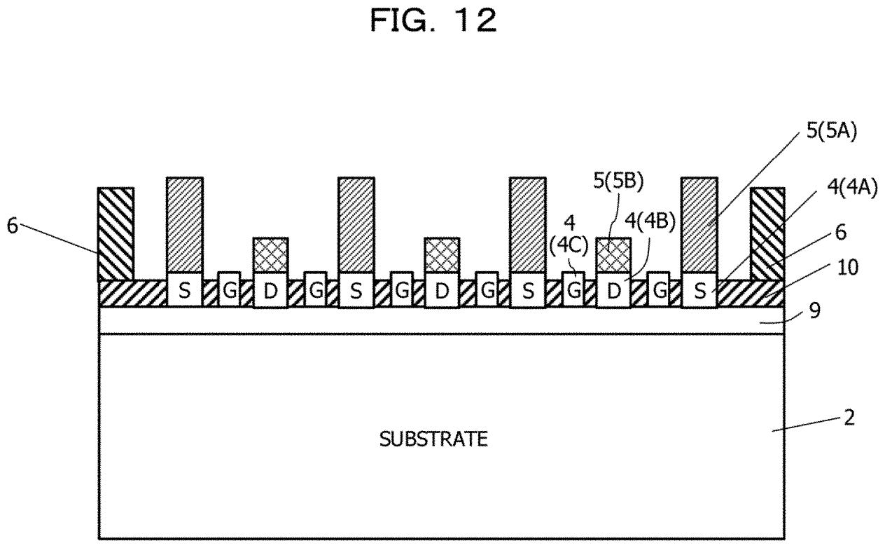

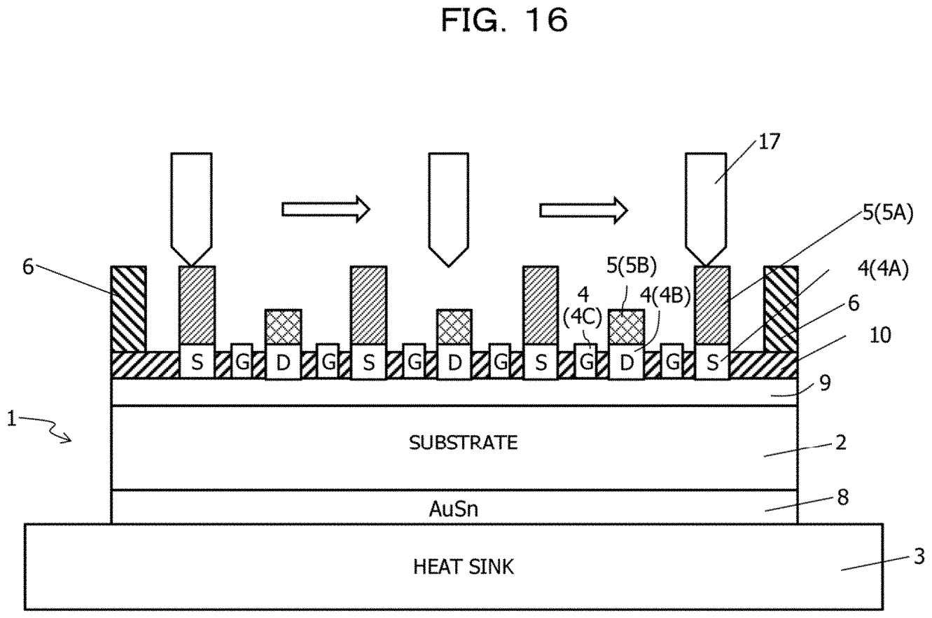

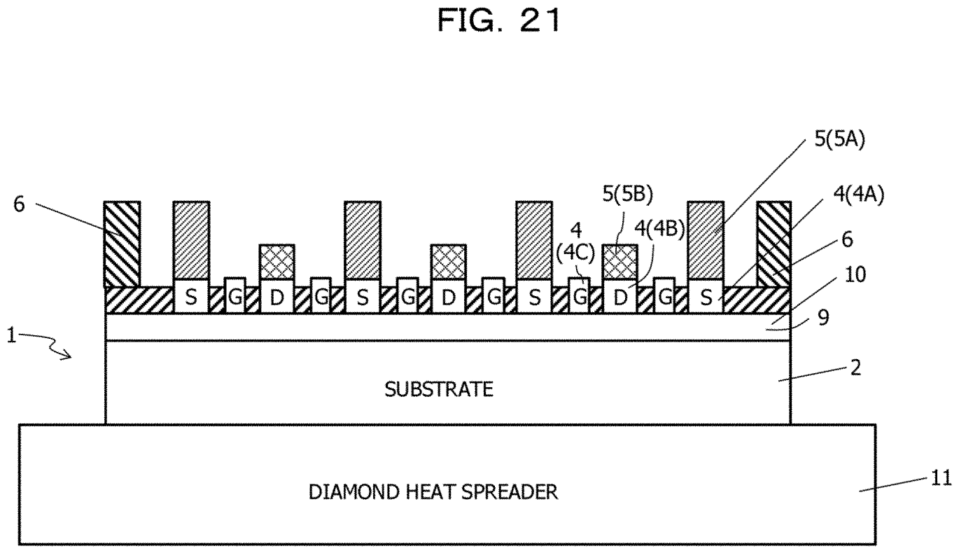

Preferably, the following steps are included before the step of providing the upper heat spreader (front heat spreader) 7: a step of forming the metal wiring 5 and the metal unit 6 (see, for example, FIGS. 12 and 21); and a step of aligning the metal wiring 5 and the metal unit 6 in the height direction (see, for example, FIGS. 16, 23, and 27). This may facilitate the fabrication.

Preferably, the following steps are included before the step of providing the upper heat spreader (front heat spreader) 7: the step of forming the metal wiring 5 and the metal unit 6 (see, for example, FIGS. 12 and 21); and a step of aligning the metal wiring 5 and the metal unit 6 in the height direction by grinding or polishing the metal wiring 5 or the metal unit 6 (see, for example, FIGS. 16, 23, and 27).

Thus, compared to the case where the front heat spreader (upper heat spreader) 7 is joined outside the semiconductor device 1 (outside the chip), the alignment in the height direction may be facilitated, and accordingly, mounting of the front heat spreader 7 may be facilitated.

Preferably, in the step of forming the metal wiring 5 and the metal unit 6, the metal wiring 5 and the metal unit 6 are simultaneously formed. This may facilitate the fabrication.

Meanwhile, the reason why the configuration and the method of manufacturing described as above are employed is as follows.

For example, for a high-power high-frequency semiconductor device (electronic device) used for long distance radio wave application fields such as a radar, radio communication, and microwave power transmission, in order to increase the radio wave arrival distance, it is expected to increase output power by using gallium nitride (GaN) or aluminum nitride (AlN) having a band gap larger than GaN as a material.

For example, a GaN HEMT is expected to be applied to a millimeter band radar system, a radio communication base station system, a server system, and so forth as a device that withstands high voltage and that is operable at high speed due to the physical properties of the GaN HEMT. For such a device, a further increase in the output power is expected to increase the radio wave arrival distance.

However, along with the increase in the output power, the device temperature increases due to self heat generation. This significantly influences degradation of the device characteristics and reliability.

In order to allow such a device to stably operate, a structure that efficiently exhausts the generated heat may become important.

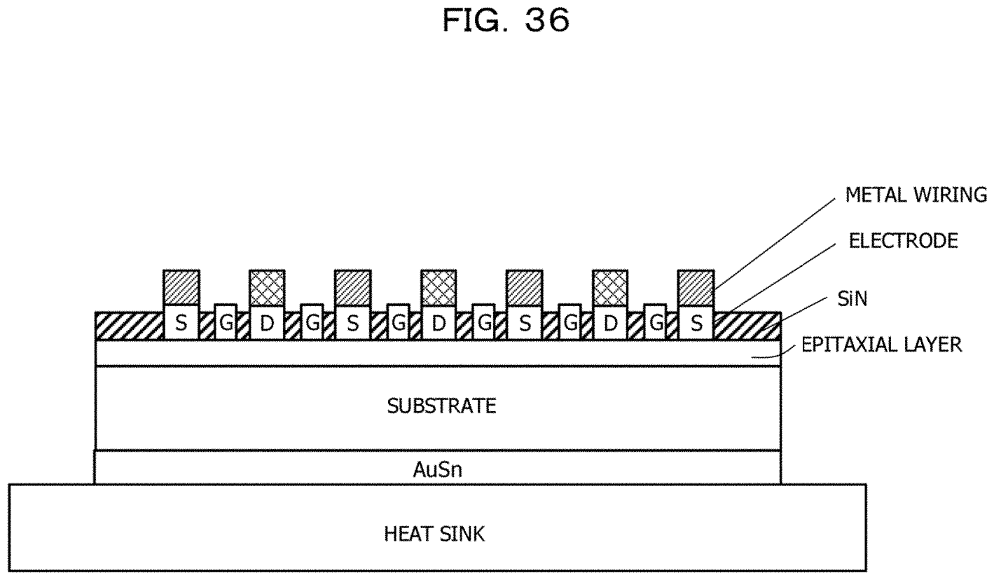

FIG. 36 illustrates the related-art heat dissipation structure for a high-power semiconductor device.

As illustrated in FIG. 36, the related-art high-power semiconductor device has a structure in which, for example, an epitaxial layer is provided over a substrate, source electrodes, drain electrodes, and gate electrodes are provided over the epitaxial layer, metal wiring is provided over the source electrodes and the drain electrodes, and a front surface of the epitaxial layer is coated with an insulating film (for example, a SiN film).

The related-art heat dissipation structure for a high-power semiconductor device structured as described above has a structure in which a heat sink is joined to the rear surface side of the substrate included in the semiconductor device with solder such as AuSn Interposed between the rear surface side of the substrate and the heat sink.

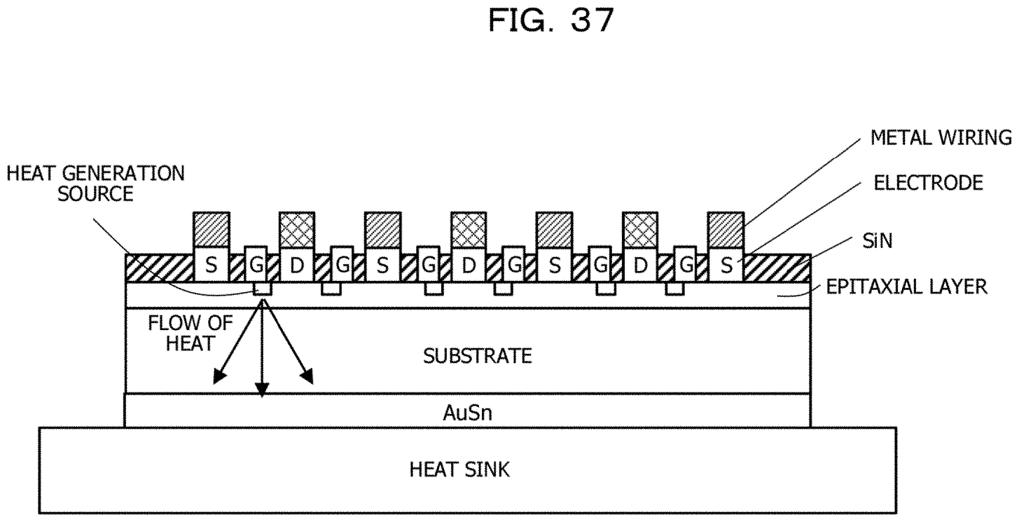

In this case, as illustrated in FIG. 37, the heat generation sources of the semiconductor device exist near drain-side gate edges. Accordingly, the heat is transferred from the heat generation sources to the substrate through the epitaxial layer, laterally spreads in accordance with the thermal conductivity of the substrate, and is exhausted (dissipated) to the heat sink joined (bonded) to a rear surface of the substrate.

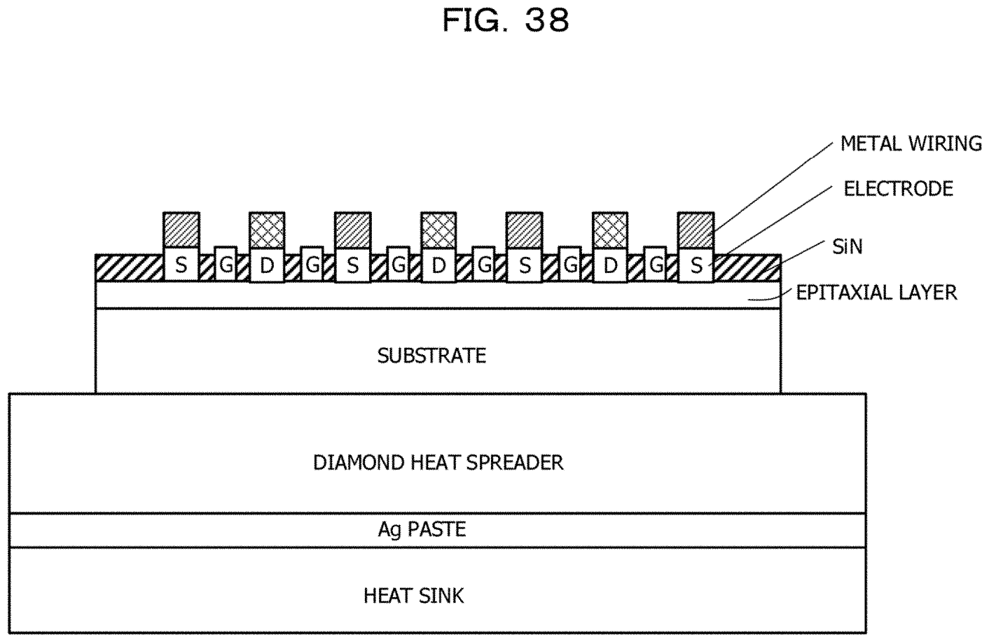

Since the output power of the GaN HEMT increases nowadays, the related-art heat dissipation structure does not suffice for heat exhaust. Accordingly, in some cases, a heat dissipation structure in which a diamond heat spreader having a very high thermal conductivity is joined to the rear surface side of the semiconductor substrate as illustrated in FIG. 38, for example, a heat dissipation structure in which the diamond heat spreader is provided between the substrate and the heat sink is employed.

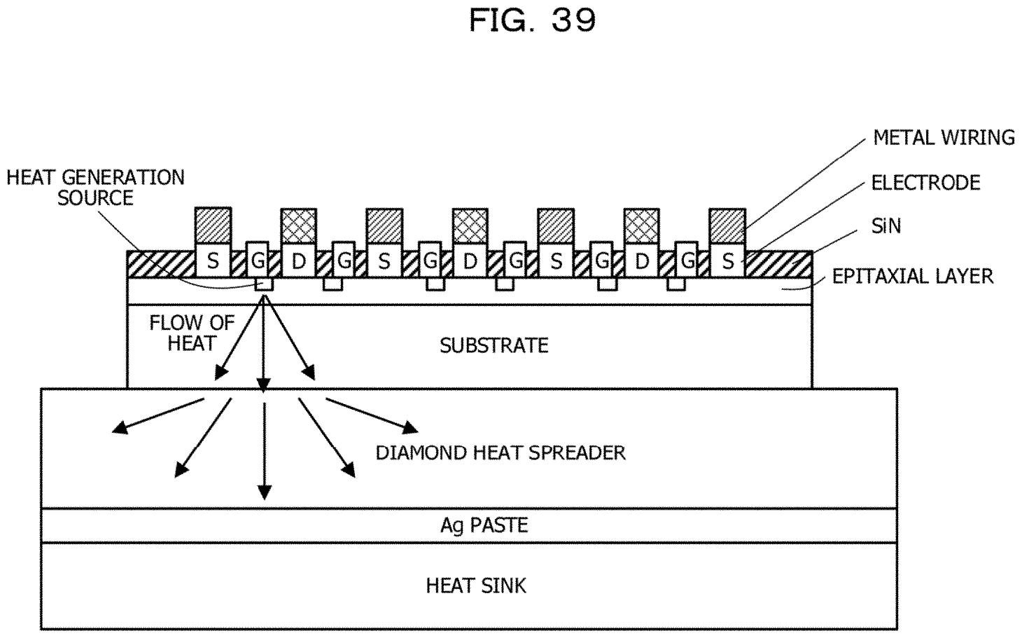

In this case, as illustrated in FIG. 39, the heat generated from the semiconductor device is further spread in the lateral direction and transferred to the heat sink. This quickly exhausts (dissipates) the heat. This may suppress the increase in the device temperature.

However, the output of the high-power high-frequency device is increasing more, and along with the increase in the output, the amount of heat generation further increases. Thus, soon there will be a situation in which further improvement of the performance is not able to be wished only with the heat dissipation through the rear surface side of the substrate.

Accordingly, in order to allow the heat to be more efficiently dissipated than with the related-art heat dissipation structure, the structure and the method of manufacturing as described above are employed.

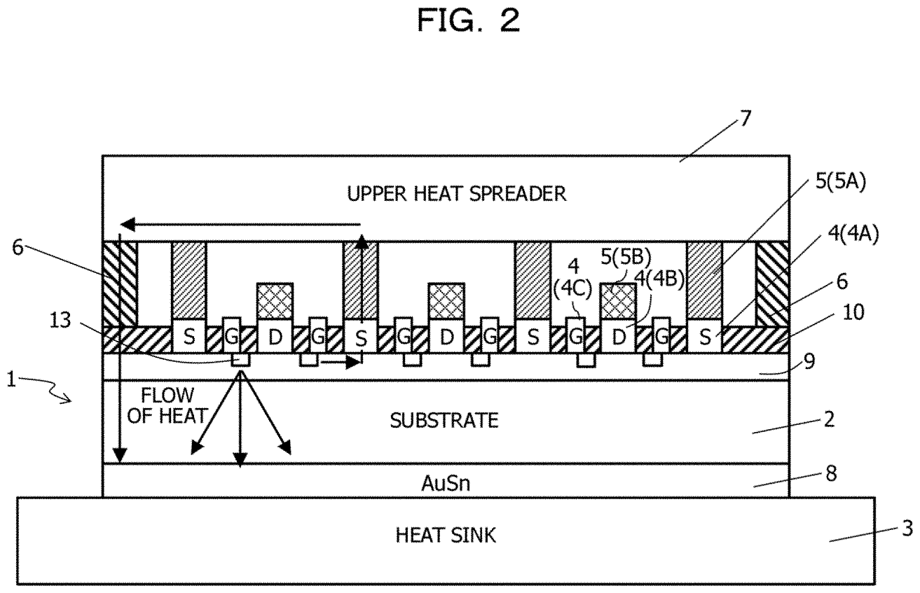

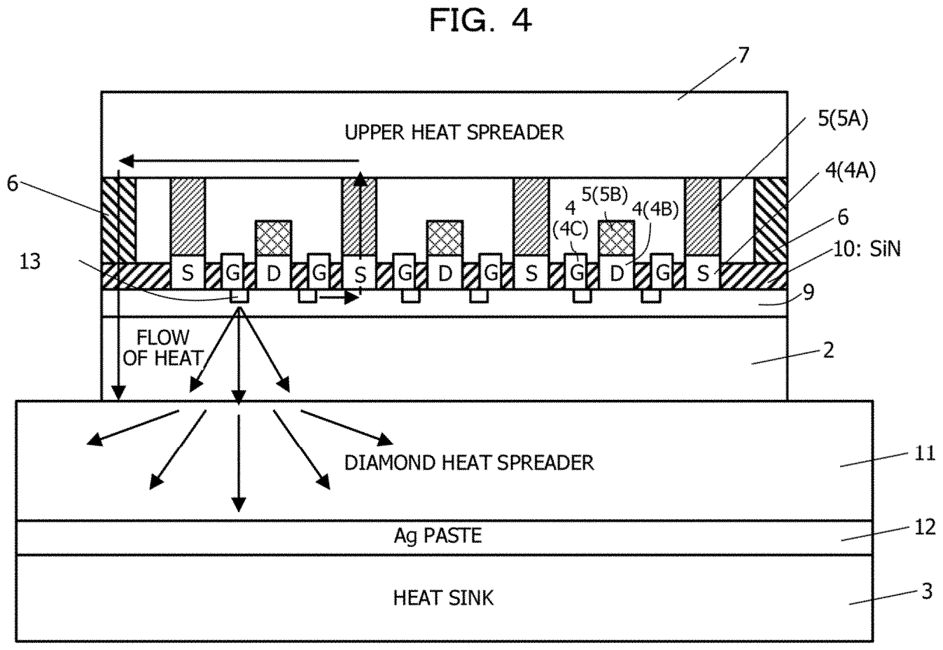

When the configurations (see, for example, FIGS. 1 and 3) and the method of manufacturing as described above are employed, as illustrated in FIGS. 2 and 4, the heat generated in heat generation sources 13 of the semiconductor device 1 is able to be transferred not only directly to the heat sink 3 under the rear surface side of the semiconductor substrate 2 but also to the upper heat spreader (front heat spreader) 7 provided over the upper portion of the semiconductor device 1 through the metal wiring 5, is able to spread, and is able to be exhausted (dissipated) to the heat sink 3 under the rear surface side of the semiconductor substrate 2 through the metal unit 6, which is provided over the outer peripheral portion, and the semiconductor substrate 2.

Thus, the heat dissipation structure for an ultra-high-power high-frequency device and a method of manufacturing this heat dissipation structure may be realized.

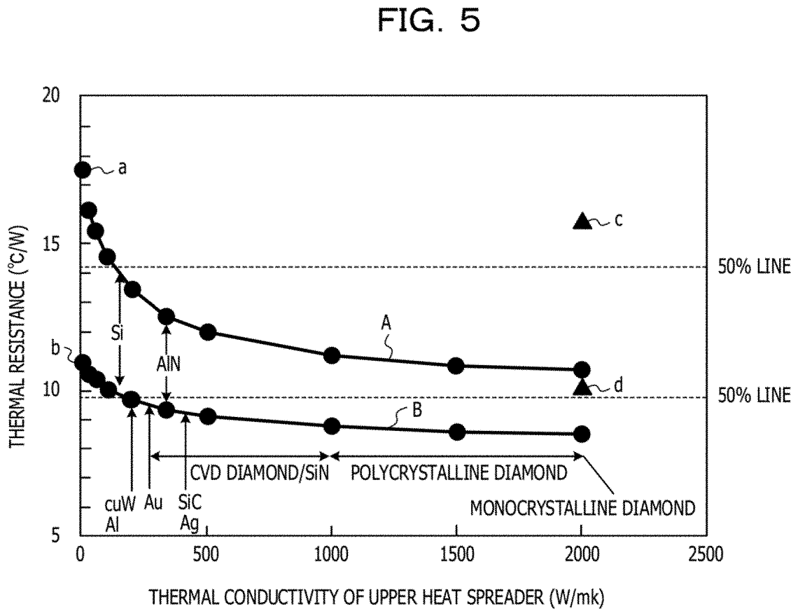

FIG. 5 illustrates simulation results of dependence of thermal resistance on the thermal conductivity of the upper heat spreader 7.

The simulation results of the heat dissipation structure illustrated in FIG. 1 and the heat dissipation structure illustrated in FIG. 3 are illustrated here. The heat dissipation structure illustrated in FIG. 1 is, for example, a heat dissipation structure which includes a heat sink structure under the rear surface side of the substrate and in which the upper heat spreader 7 is coupled via the metal unit 6 provided over the outer peripheral portion of the semiconductor device 1. The heat dissipation structure illustrated in FIG. 3 is, for example, a heat dissipation structure configured by adding to the heat dissipation structure illustrated in FIG. 1 the diamond heat spreader 11 that has a very high thermal conductivity between the rear surface of the semiconductor substrate 2 and the heat sink 3.

In FIG. 5, a solid line A indicates the simulation result of the heat dissipation structure illustrated in FIG. 1, and a solid line B indicates the simulation result of the heat dissipation structure illustrated in FIG. 3.

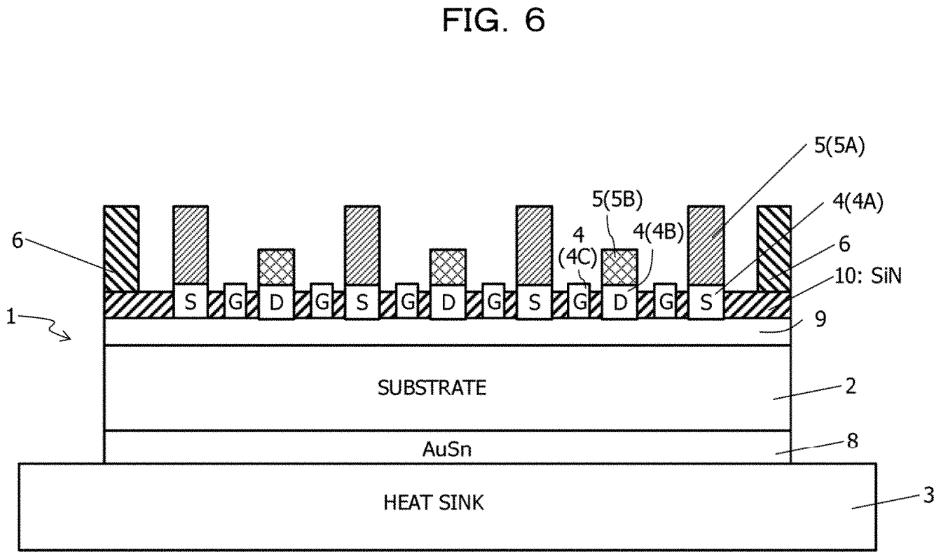

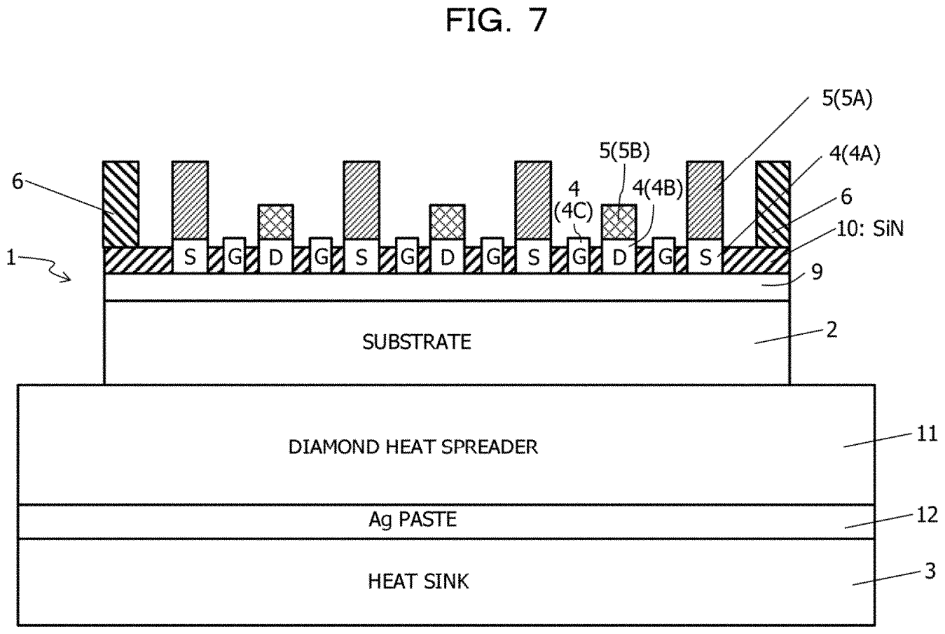

Thermal resistances of the heat dissipation structures in which the upper heat spreader 7 (see FIGS. 6 and 7) is not provided compared to the heat dissipation structures illustrated in FIGS. 1 and 3 are plotted at positions where the thermal conductivity of the upper heat spreader 7 is 0.

In FIG. 5, the thermal resistance of the heat dissipation structure illustrated in FIG. 6 is denoted by a reference sign a, and the thermal resistance of the heat dissipation structure illustrated in FIG. 7 is denoted by a reference sign b.

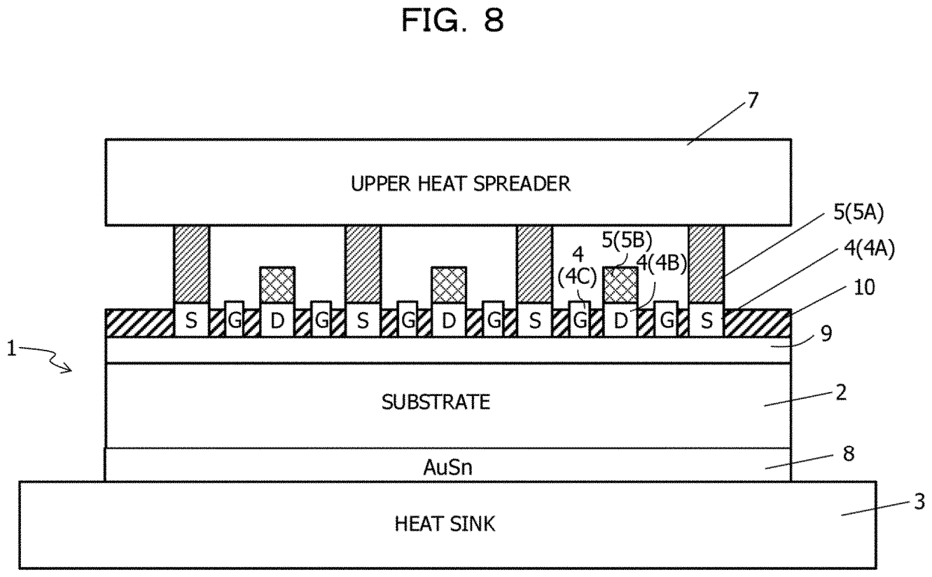

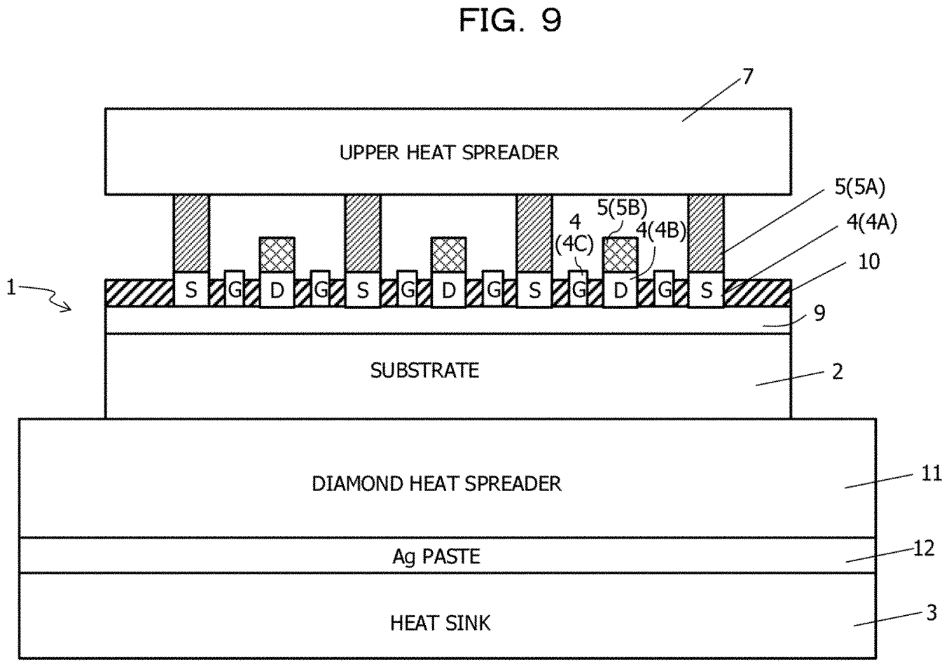

Triangular marks are used to plot the thermal resistances of heat dissipation structures in which, compared to the heat dissipation structures illustrated in FIGS. 1 and 3, a monocrystalline diamond heat spreader having the highest thermal conductivity (about 2000 W/mK) is used as the upper heat spreader 7 and the metal unit 6 is not provided over the outer peripheral portion (chip outer periphery) of the semiconductor device 1 (heat dissipation structures in which only the source wiring 5A is coupled to the upper heat spreader 7; see FIGS. 8 and 9).

In FIG. 5, the thermal resistance of the heat dissipation structure illustrated in FIG. 8 is denoted by a reference sign c, and the thermal resistance of the heat dissipation structure illustrated in FIG. 9 is denoted by a reference sign d. The heat dissipation structures illustrated in FIGS. 8 and 9 are heat dissipation structures in which the upper heat spreader 7 is not coupled to the heat sink 3 or the diamond heat spreader 11.

As a result, it may be understood that, as illustrated in FIG. 5, the heat dissipation structures illustrated in FIGS. 1 and 3 dissipate heat more efficiently than the related-art heat dissipation structures, for example, the heat dissipation structures without the upper heat spreader 7 (see FIGS. 6 and 7).

For example, it may be understood that, when the heat dissipation structures illustrated in FIGS. 1 and 3 are used and the upper heat spreader 7 is formed of a material having a thermal conductivity of about 200 W/mK or higher, the thermal resistances are able to be reduced to 50% lines or smaller as illustrated in FIG. 5 and heat is sufficiently dissipated compared to the related-art heat dissipation structure, for example, the heat dissipation structures without the upper heat spreader 7 (see FIGS. 6 and 7).

Here, the rate “50%” of the 50% lines indicates half (50% of) the thermal resistances observed when the thermal resistances of the heat dissipation structures illustrated in FIGS. 1 and 3 become the lowest (when the monocrystaline diamond heat spreader having the highest thermal conductivity (about 2000 W/mK) is used as the upper heat spreader 7). When the thermal resistances are able to be reduced to the 50% lines or smaller, it may be regarded that heat is sufficiently dissipated with respect to the thermal resistances of the heat dissipation structures without the upper heat spreader 7 (see FIGS. 6 and 7).

For example, when the thermal resistances of the heat dissipation structures are reduced with respect to the thermal resistances of the heat dissipation structures without the upper heat spreader 7 (see FIGS. 6 and 7) by 50% or greater of the thermal resistances observed when the thermal resistances become the lowest, it may be regarded that heat is sufficiently dissipated.

Even when the monocrystalline diamond heat spreader having the highest thermal conductivity (about 2000 W/mK) is used as the upper heat spreader 7, in the case where the heat dissipation structures are not provided with the metal unit 6 over the outer peripheral portion (chip outer periphery) of the semiconductor device 1 (see FIGS. 8 and 9), as plotted with the triangular marks in FIG. 5 (see reference signs c and d), the effect of reducing the thermal resistance is small. Thus, it may be understood that heat dissipation (heat exhaust) from the metal unit 6 to the heat sink 3 under the rear surface side of the semiconductor substrate 2 is important.

FIG. 10 illustrates simulation results of dependence of thermal resistance on the width of the metal unit.

Here, the simulation results when the monocrystalline diamond heat spreader is used as the upper heat spreader 7 in the heat dissipation structures illustrated in FIGS. 1 and 3 are illustrated.

In FIG. 10, a solid line A indicates the simulation result of the heat dissipation structure illustrated in FIG. 1, and a solid line B indicates the simulation result of the heat dissipation structure illustrated in FIG. 3.

The thermal resistances of the heat dissipation structures in which, compared to the heat dissipation structures illustrated in FIGS. 1 and 3, the metal unit 6 is not provided over the outer peripheral portion (chip outer periphery) of the semiconductor device 1 (heat dissipation structures in which only the source wiring 5A is coupled to the upper heat spreader 7; see FIGS. 8 and 9) are plotted at positions corresponding to the metal width of 0.

In FIG. 10, the thermal resistance of the heat dissipation structure illustrated in FIG. 8 is denoted by a reference sign a, and the thermal resistance of the heat dissipation structure illustrated in FIG. 9 is denoted by a reference sign b.

As illustrated in FIG. 10, it may be understood that, when the width (for example, see reference sign W in FIG. 18) of the metal unit 6 coupled to the monocrystalline diamond heat spreader as the upper heat spreader 7 is about 10 μm or greater, a half or more of the effect obtained with the metal unit 6 having a width of about 500 μm or greater is obtained and heat is sufficiently dissipated.

Here, the rate “50%” of the 50% lines indicates half (50% of) the thermal resistances observed when the metal unit 6 having a width of about 500 μm or greater with which the thermal resistances are sufficiently reduced is used. When the thermal resistances are able to be reduced to the 50% lines or smaller, it may be regarded that heat is sufficiently dissipated with respect to the thermal resistances of the heat dissipation structures in which the metal unit 6 is not provided over the outer peripheral portion (chip outer periphery) of the semiconductor device 1 (heat dissipation structures in which only the source wiring 5A is coupled to the upper heat spreader 7; see FIGS. 8 and 9).

For example, when the thermal resistances are able to be reduced by 50% or more of the thermal resistances observed when the thermal resistances are sufficiently reduced from the thermal resistances of the heat dissipation structures in which the metal unit 6 is not provided over the outer peripheral portion (chip outer periphery) of the semiconductor device 1 (heat dissipation structures in which only the source wiring 5A is coupled to the upper heat spreader 7; see FIGS. 8 and 9), it may be regarded that heat is sufficiently dissipated.

Accordingly, the heat dissipation structure for the semiconductor device 1 and the method of manufacturing the heat dissipation structure for the semiconductor device 1 according to the present embodiment may produce an effect of more efficiently dissipating heat than the related-art heat dissipation structure.

Hereinafter, configuration examples are described.

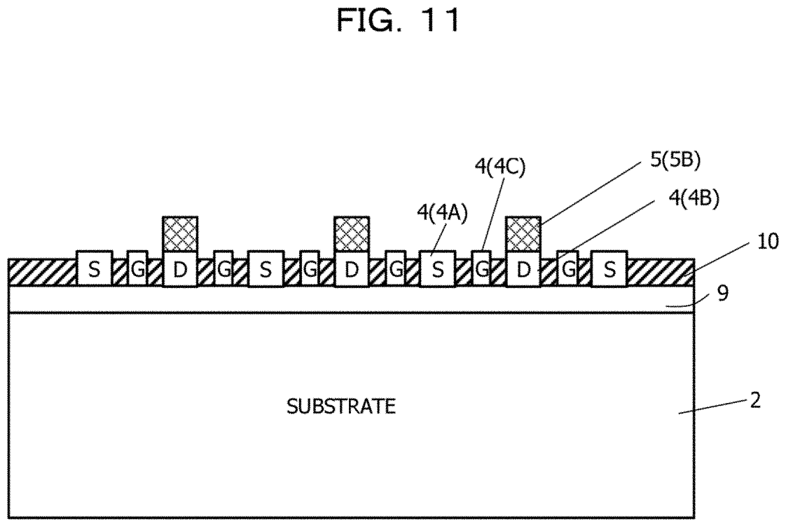

Initially, a first configuration example is described with reference to FIGS. 11 to 19.

As illustrated in FIG. 11, first, Au plating having a thickness of about 5 μm is formed as the drain wiring 5B (metal wiring 5) over the drain electrodes 4B out of the gate electrodes 4C, the source electrodes 4A, and the drain electrode 4B as the electrodes 4 fabricated over the epitaxial layer 9 grown over the AlN substrate 2.

Then, as illustrated in FIG. 12, Au plating having a thickness of about 30 μm is formed over the source electrodes 4A and a chip outer peripheral portion, on which cutting for dicing is planned to be performed, respectively as the source wiring 5A (metal wiring 5) and the metal unit 6 to be coupled to the upper heat spreader 7.

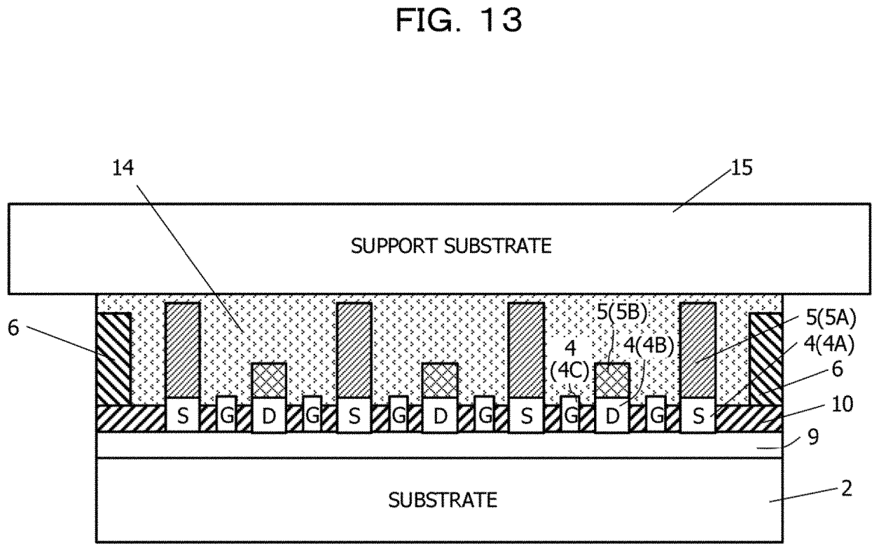

Then, as illustrated in FIG. 13, an adhesive 14 is applied to a front surface of a wafer to a thickness of about 50 μm, and the wafer is stuck to a support substrate 15. After that, the rear surface of the AlN substrate 2 is ground to reduce the thickness of the AlN substrate 2 to a predetermined film thickness. Here, the thickness of the AlN substrate 2 is reduced to about 50 μm.

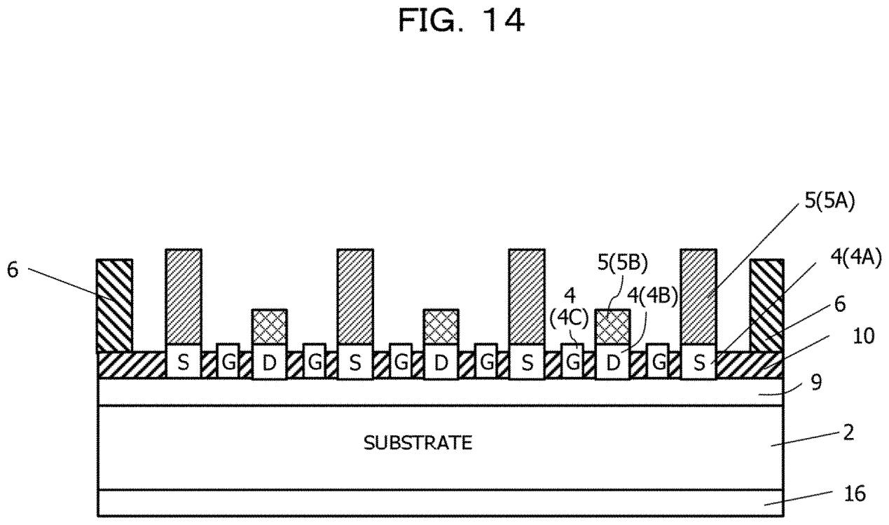

Then, as illustrated in FIG. 14, the rear surface of the AlN substrate 2 is Au plated to a thickness of about 3 μm to form a Au film 16. Then, the wafer is removed from the support substrate 15 and the adhesive 14 is removed. Then, the wafer is diced into chips.

Next, as illustrated in FIG. 15, the chip 1 is mounted over the heat sink 3 formed of, for example, CuMo, CuW, or the like, by using, for example, the solder 8 such as AuSn.

Here, as illustrated in FIG. 16, in order to reduce a difference in height between the source wiring 5A and the metal unit 6 and correct the parallelism at the time of mounting, the source wiring 5A and the metal unit 6 are ground by using a diamond bit 17 so that the heights of the source wiring 5A and the metal unit 6 are about 25 μm.

Then, as illustrated in FIGS. 17 and 18, the source wiring 5A and the metal unit 6 are coupled to a Au plate that is to serve as the upper heat spreader 7 by room-temperature joining.

Here, argon (Ar) beams are radiated to the chip 1 and the Au plate as the upper heat spreader 7 in a vacuum. Thus, the source wiring 5A and the metal unit 6 which are formed of Au and front surfaces of which are activated are joined to the Au plate as the upper heat spreader 7 at room temperature.

The source wiring 5A, the drain wiring 5B, and the gate electrodes 4 C are coupled to a source pad 18, a drain pad 19, and a gate pad 20, respectively.

In this manner, the heat dissipation structure of the high-power device 1 of the first configuration example is able to be manufactured.

FIG. 18 is a top view. FIGS. 11 to 17 are sectional views taken along line A-A′ in FIG. 18.

With the high-power device 1 of the first configuration example manufactured as described above, the device 1 may be cooled more efficiently than with the related-art heat dissipation structure by transferring the heat generated in the high-power device 1 not only directly to the heat sink 3 under the rear surface side of the substrate but also to the upper heat spreader 7 provided over the upper portion of the device 1 through the metal wiring 5, spreading the heat transferred to the upper heat spreader 7, and exhausting the heat to the heat sink 3 under the rear surface side of the substrate through the metal unit 6, which is provided over the outer peripheral portion, and the substrate 2 (see, for example, FIG. 2).

Herein, in order to stabilize the ground potential and reduce the inductance, the source wiring 5A and the upper heat spreader 7 are coupled to each other. However, the drain wiring 58 and the upper heat spreader 7 may be coupled to each other.

Herein, the case where the AlN substrate exemplifies the substrate 2 is described. Alternatively, the substrate 2 may be formed of, for example, Si, SiC, GaN, or the like. Also in this case, a similar effect may be obtained.

The source wiring 5A and the metal unit 6 may be formed of a material other than Au. For example, the source wiring 5A and the metal unit 6 may be fabricated by Cu plating or Ag plating. The upper heat spreader 7 may be formed of a material other than Au. The upper heat spreader 7 may be formed of a material having a thermal conductivity of about 200 W/mK or higher, for example, a material selected from the group consisting of CuMo, CuW, Al, GaN, Cu, Au, Ag, AlN, SiC, graphite, and diamond.

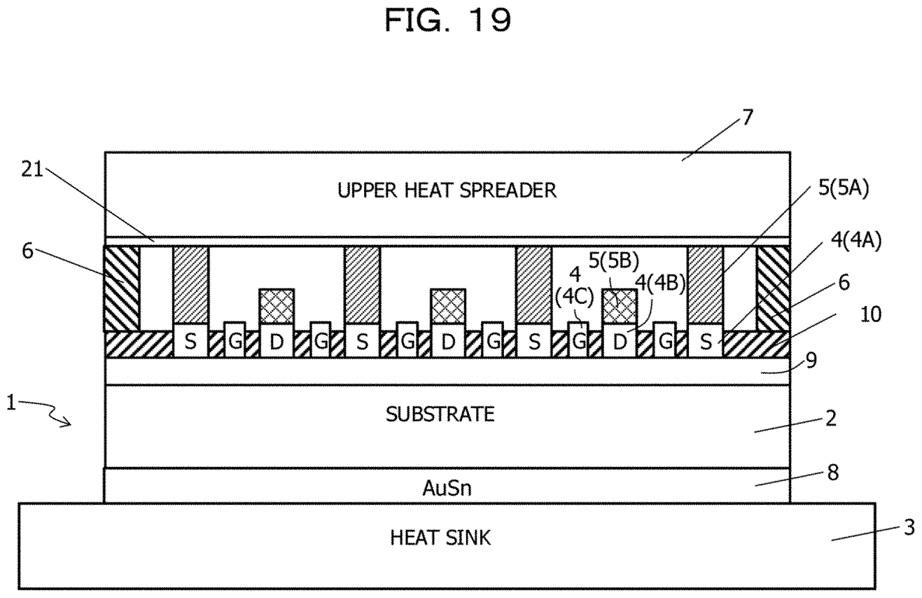

When the material of the source wiring 5A and the metal unit 6 is different from the material of the upper heat spreader 7, joining strength may be improved by, as illustrated in FIG. 19, forming a metal film 21 such as, for example, a Au film or a Ag film under the upper heat spreader 7 by sputtering, and then joining the metal film 21 to the source wiring 5A and the metal unit 6 at room temperature.

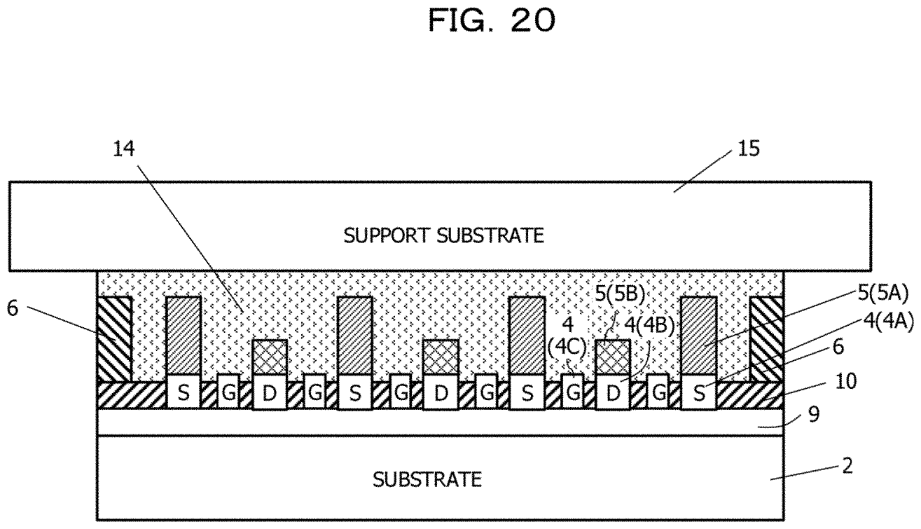

Next, a second configuration example is described with reference to FIGS. 20 to 25.

The second configuration example is described with an example of the heat dissipation structure that includes the diamond heat spreader 11 under the rear surface side of the substrate.

First, the steps of the second configuration example are similar to the steps of the above-described first configuration example (see FIGS. 11 to 13) to the step of grinding the rear surface of the AlN substrate 2 so as to reduce the film thickness to the predetermined film thickness. Here, the thickness of the AlN substrate 2 is reduced to about 60 μm.

Next, as illustrated in FIG. 20, in order to set the roughness of the rear surface of the AlN substrate 2 to 1 nm or smaller, the rear surface of the AlN substrate 2 is polished by about 10 μm by chemical mechanical polishing (CMP).

Then, as illustrated in FIG. 21, the rear surface of the AlN substrate 2 and the diamond heat spreader 11 are joined to each other by room-temperature joining.

The AlN substrate 2 and the diamond heat spreader 11 are joined to each other at room temperature by using a technique in which the rear surface of the AlN substrate 2 and the front surface of the diamond heat spreader 11 are activated by the Ar beam radiation in a vacuum or a technique in which a thin metal film such as a Ti film, for example, is formed over the front surface of the diamond heat spreader 11 or under the rear surface of the AlN substrate 2 and over the front surface of the diamond heat spreader 11.

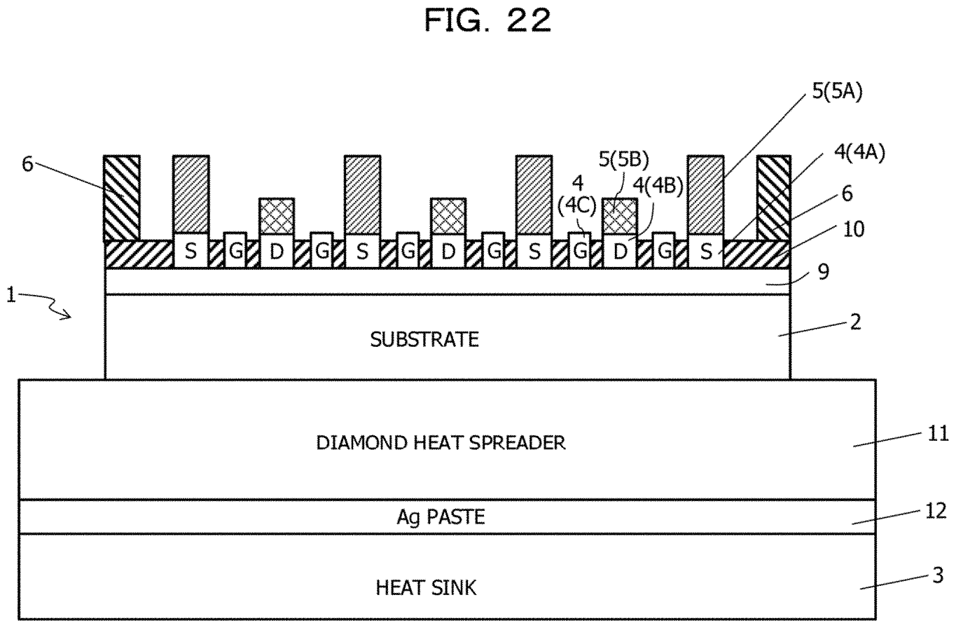

Next, as illustrated in FIG. 22, the chip 11s mounted over the heat sink 3 formed of, for example, CuMo, CuW, or the like by using a material such as the Ag paste 12 or the like.

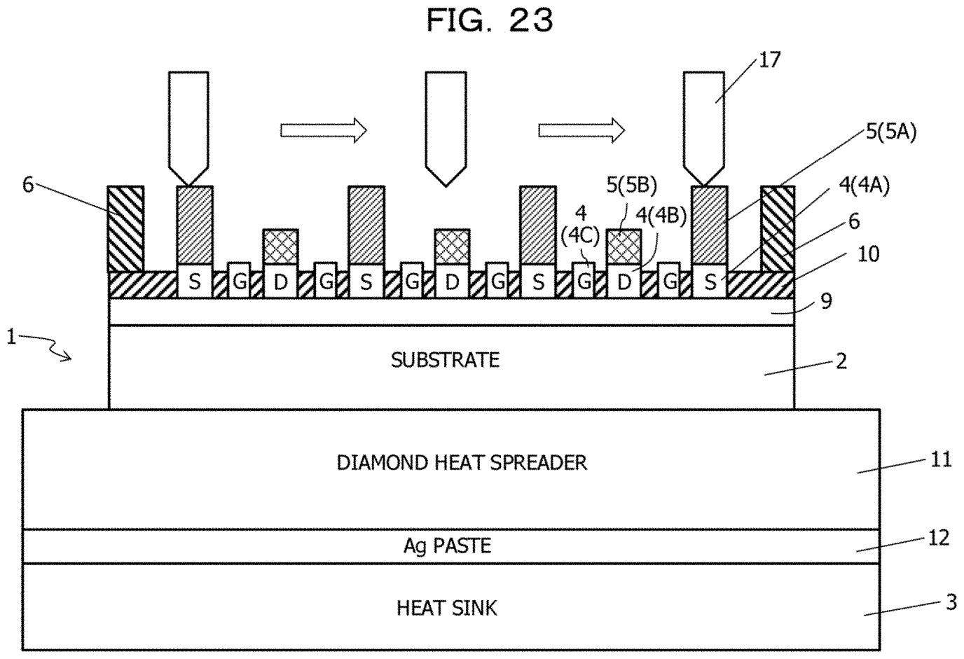

Here, as illustrated in FIG. 23, in order to reduce a difference in height between the source wiring 5A and the metal unit 6 and correct the parallelism at the time of mounting, the source wiring 5A and the metal unit 6 are ground by using the diamond bit 17 so that the heights of the source wiring 5A and the metal unit 6 are about 25 μm.

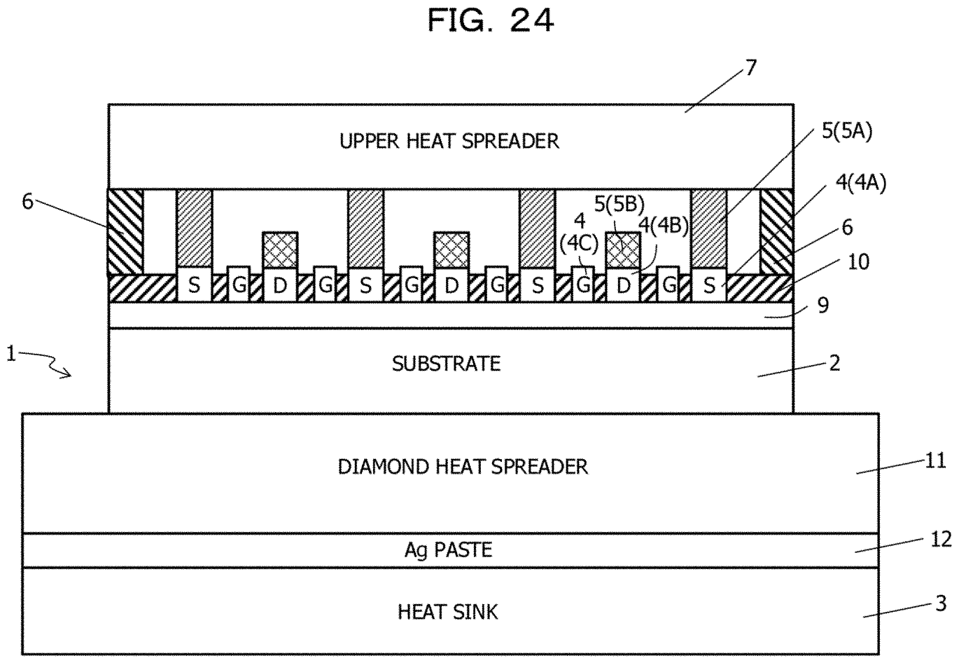

Then, as illustrated in FIG. 24, the source wiring 5A and the metal unit 6 are coupled to a Au plate that is to serve as the upper heat spreader 7 by room-temperature joining.

Here, argon (Ar) beams are radiated to the chip 1 and the Au plate as the upper heat spreader 7 in a vacuum. Thus, the source wiring 5A and the metal unit 6 which are formed of Au and the front surfaces of which are activated are joined to the Au plate as the upper heat spreader 7 at room temperature.

In this manner, the heat dissipation structure of the high-power device 1 of the second configuration example is able to be manufactured.

With the high-power device 1 of the second configuration example manufactured as described above, the device 1 may be cooled more efficiently than in the case of the heat dissipation structure of the first configuration example described above by transferring the heat generated in the high-power device 1 not only directly to the diamond heat spreader 11 under the rear surface side of the substrate but also to the upper heat spreader 7 provided over the upper portion of the device 1 through the metal wiring 5A, spreading the heat transferred to the upper heat spreader 7, and exhausting the heat to the heat sink 3 under the rear surface side of the substrate through the metal unit 6, which is provided over the outer peripheral portion, and the substrate 2 (see, for example, FIG. 4).

Herein, in order to stabilize the ground potential and reduce the inductance, the source wiring 5A and the upper heat spreader 7 are coupled to each other. However, the drain wiring 58 and the upper heat spreader 7 may be coupled to each other.

Herein, the case where the AlN substrate exemplifies the substrate 2 is described. Alternatively, the substrate 2 may be formed of, for example, Si, SiC, GaN, or the like. Also in this case, a similar effect may be obtained.

The source wiring 5A and the metal unit 6 may be formed of a material other than Au. For example, the source wiring 5A and the metal unit 6 may be fabricated by Cu plating or Ag plating. The upper heat spreader 7 may be formed of a material other than Au. The upper heat spreader 7 may be formed of a material having a thermal conductivity of about 200 W/mK or higher, for example, a material selected from the group consisting of CuMo, CuW, Al, GaN, Cu, Au, Ag, AlN, SiC, graphite, and diamond.

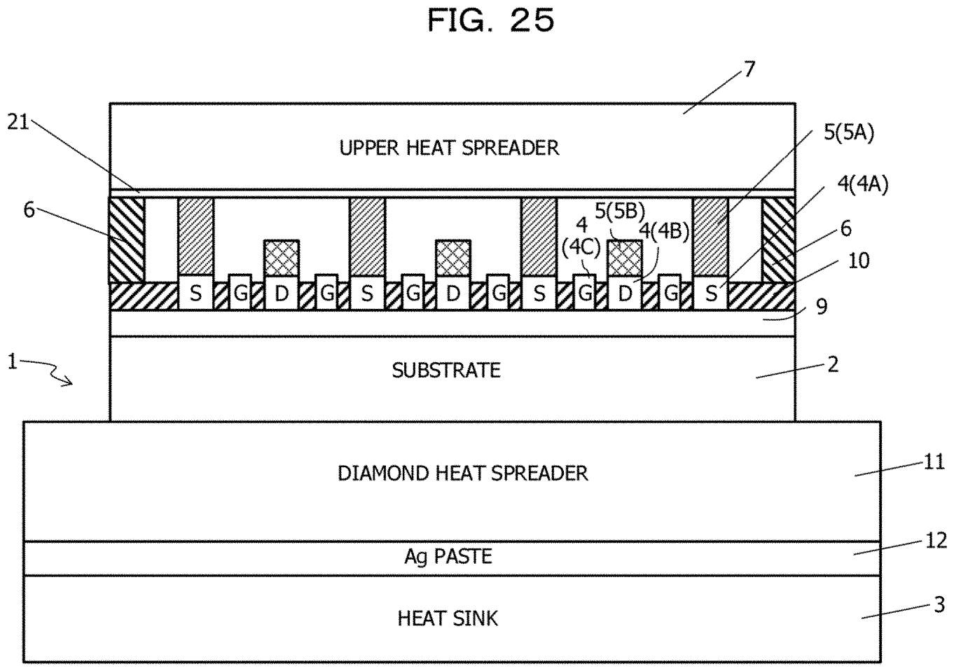

When the material of the source wiring 5A and the metal unit 6 is different from the material of the upper heat spreader 7, the joining strength may be improved by, as illustrated in FIG. 25, forming the metal film 21 such as, for example, a Au film or a Ag film under the upper heat spreader 7 by sputtering, and then joining the metal film 21 to the source wiring 5A and the metal unit 6 at room temperature.

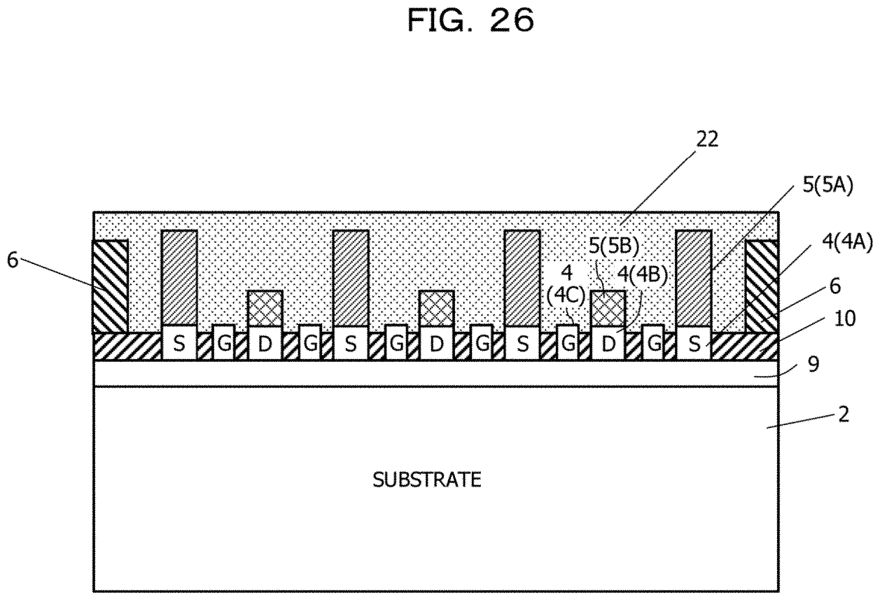

Next, a third configuration example is described with reference to FIGS. 26 to 34.

The third configuration example is described with an example of the heat dissipation structure in which a space over the front surface side of the device 1 is filled with an interlayer insulating film 22.

First, Cu plating having a thickness of about 30 μm is formed over the source electrodes 4A and a chip outer peripheral portion, on which cutting for dicing is planned to be performed, respectively as the source wiring 5A and the metal unit 6 to be coupled to the upper heat spreader 7. The steps of the third configuration example are similar to the steps of the above-described first configuration example (see FIGS. 11 and 12) to this step.

Next, as illustrated in FIG. 26, the interlayer insulating film 22 having a thickness of about 40 μm is applied to the front surface of the wafer and cured at about 250° C.

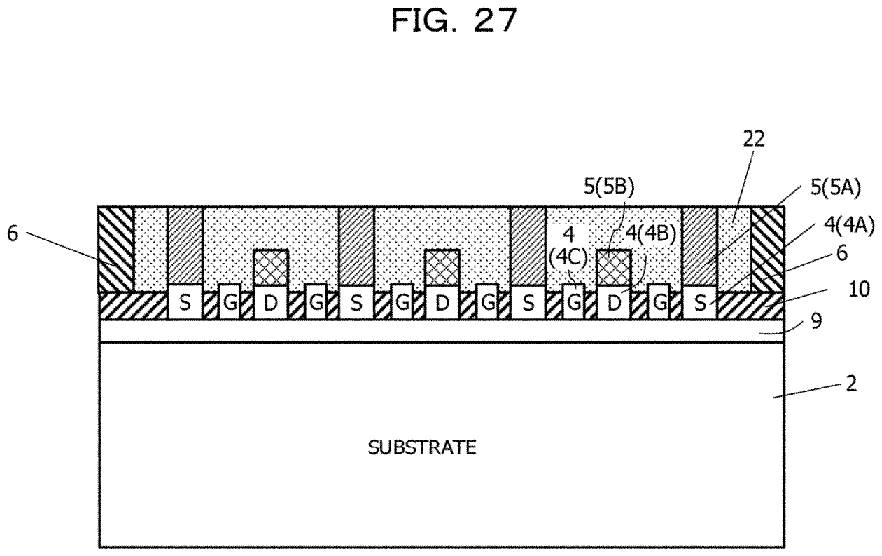

Then, as illustrated in FIG. 27, the source wiring 5A, the metal unit 6, and the interlayer insulating film 22 are planarized by a damascene process. The thickness of the interlayer insulating film 22 is processed to about 25 μm.

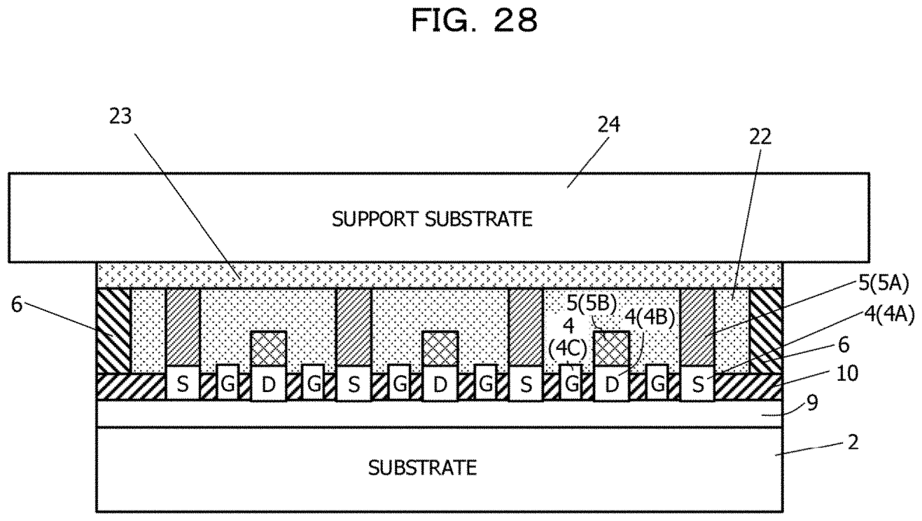

Then, as illustrated in FIG. 28, an adhesive 23 is applied to the front surface of the wafer to a thickness of about 10 μm, and the wafer is stuck to a support substrate 24. Then, the rear surface of the AlN substrate 2 is ground to reduce the thickness of the AlN substrate 2 to a predetermined film thickness. Here, the thickness of the AlN substrate 2 is reduced to about 30 μm.

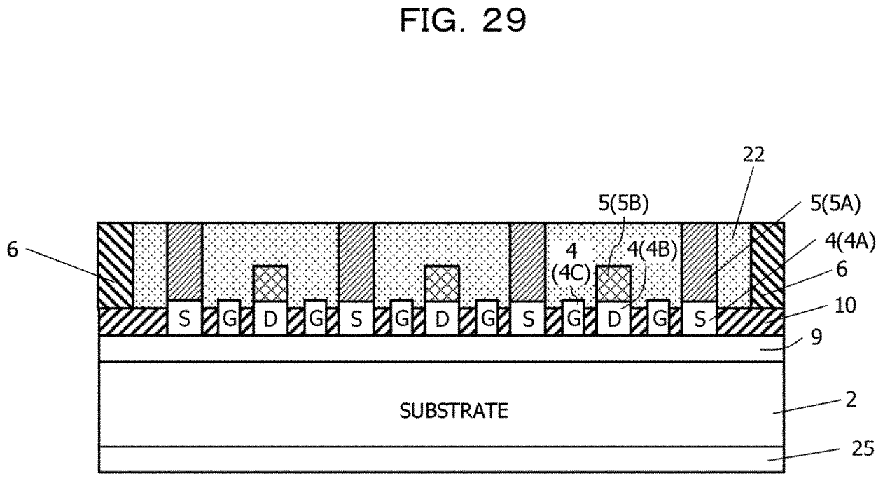

Then, as illustrated in FIG. 29, the rear surface of the AlN substrate 2 is Au plated to a thickness of about 3 μm to form a Au film 25. Then, the wafer is removed from the support substrate 24 and the adhesive 23 is removed. Then, the wafer is diced into chips.

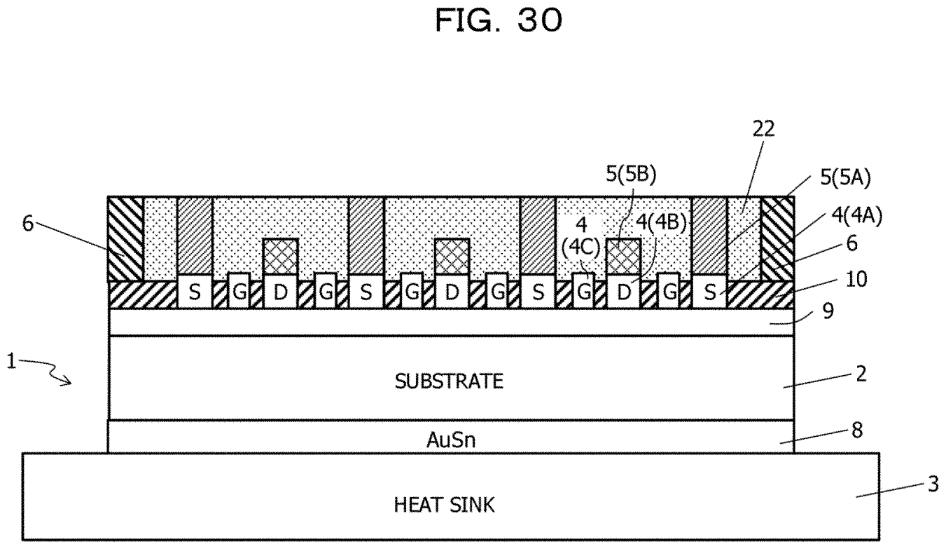

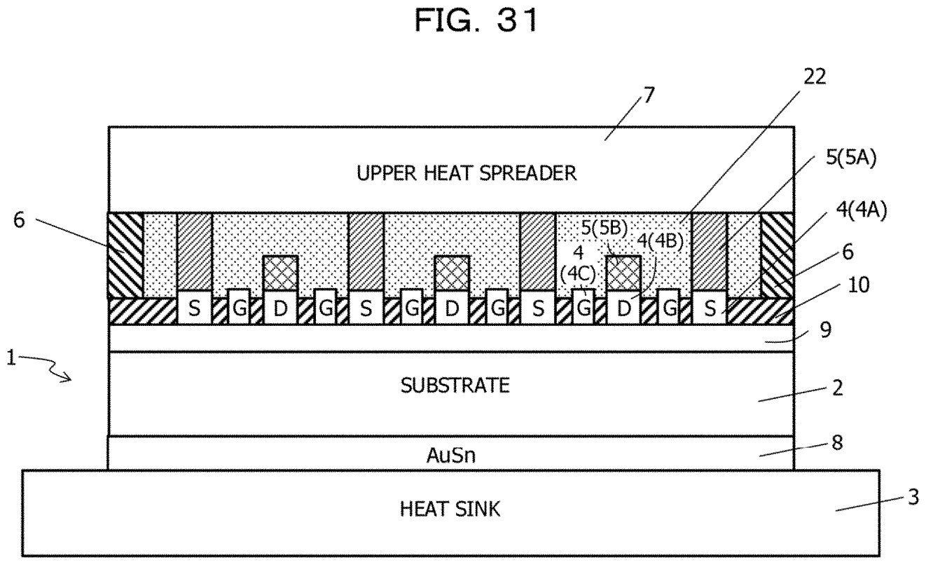

Then, as illustrated in FIG. 30, the chip 1 is mounted over the heat sink 3 formed of, for example, CuMo, CuW, or the like by using, for example, the solder 8 such as AuSn. Then, as illustrated in FIG. 31, the source wiring 5A and the metal unit 6 are coupled to a Cu plate that is to serve as the upper heat spreader 7 by room-temperature joining.

Here, argon (Ar) beams are radiated to the chip 1 and the Cu plate as the upper heat spreader 7 in a vacuum. Thus, the source wiring 5A and the metal unit 6 which are formed of Cu and the front surfaces of which are activated are joined to the Cu plate as the upper heat spreader 7 at room temperature. However, the interlayer insulating film 22 and the upper heat spreader 7 are not joined to each other.

In this manner, the heat dissipation structure of the high-power device 1 of the third configuration example is able to be manufactured.

In the high-power device 1 of the third configuration example manufactured as described above, the thickness of the AlN substrate 2 may be reduced compared to the thickness of the AlN substrate 2 of the first configuration example described above by planarizing the front surface of the device by using the interlayer insulating film 22. Thus, heat generated in the device 1 may be more efficiently exhausted to the heat sink 3 under the rear surface side of the substrate than in the case of the above-described first configuration example. The heat is able to be transferred to the upper heat spreader 7 provided over the upper portion of the device 1 through the metal wiring 5, is able to spread, and is able to be exhausted to the heat sink 3 under the rear surface side of the substrate through the metal unit 6, which is provided over the outer peripheral portion, and the substrate 2. Thus, the device 1 may be cooled more efficiently than with the related-art heat dissipation structure.

Herein, in order to stabilize the ground potential and reduce the inductance, the source wiring 5A and the upper heat spreader 7 are coupled to each other. However, the drain wiring 58 and the upper heat spreader 7 may be coupled to each other.

Herein, the case where the AlN substrate exemplifies the substrate 2 is described. Alternatively, the substrate 2 may be formed of, for example, Si, SiC, GaN, or the like. Also in this case, a similar effect may be obtained.

The source wiring 5A and the metal unit 6 may be formed of a material other than Cu. For example, the source wiring 5A and the metal unit 6 may be fabricated by Au plating or Ag plating.

The upper heat spreader 7 may be formed of a material having a thermal conductivity of about 200 W/mK or higher, for example, a material selected from the group consisting of CuMo, CuW, Al, GaN, Cu, Au, Ag, AlN, SiC, graphite, and diamond.

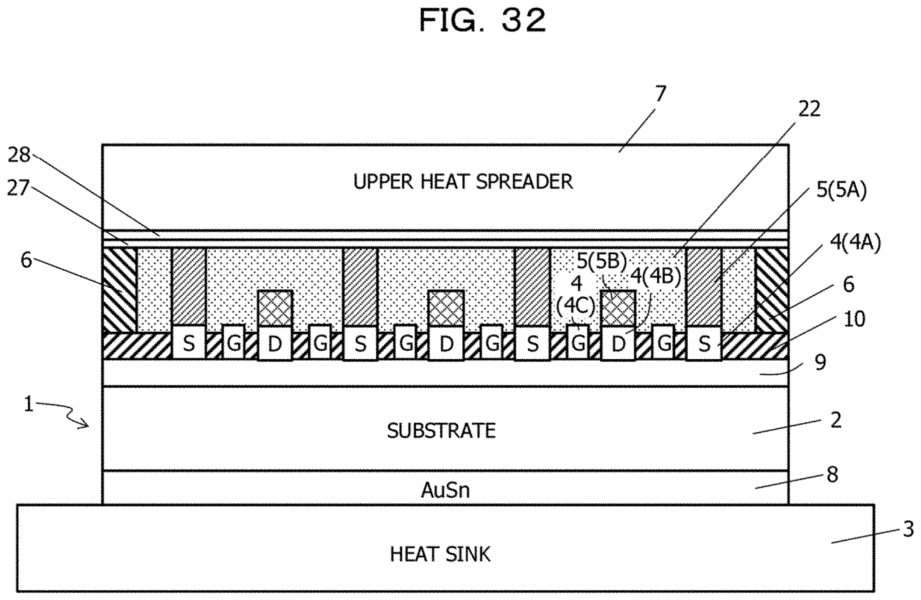

The joining strength may be improved by, as illustrated in FIG. 32, forming a metal film 27 such as, for example, Ti films over the interlayer insulating film 22, the source wiring 5A, and the metal unit 6 and a metal film 28 under the upper heat spreader 7 by sputtering and joining the metal films 27 and 28 to each other by room-temperature joining.

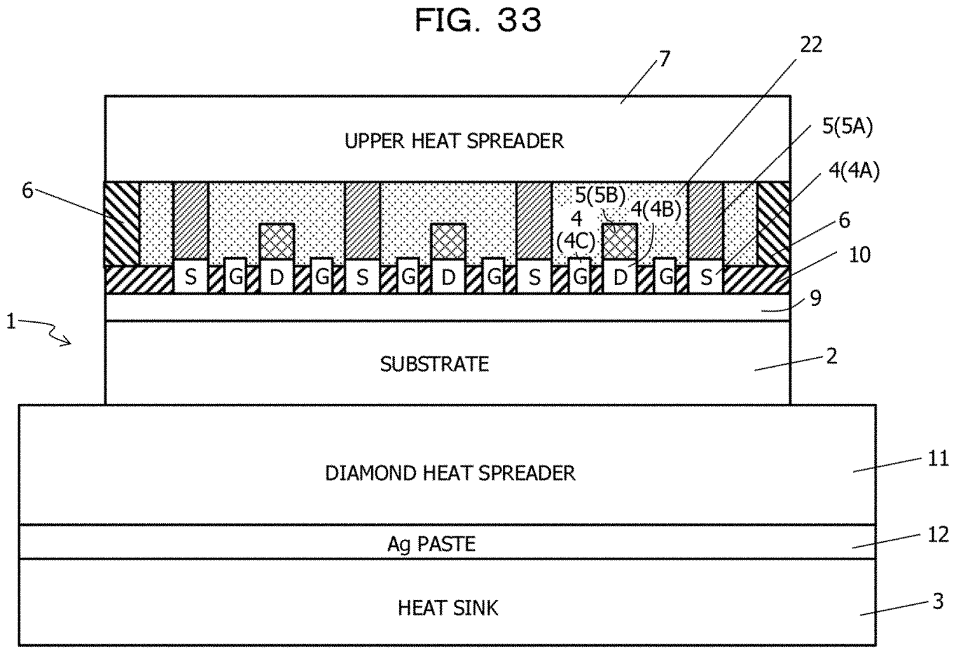

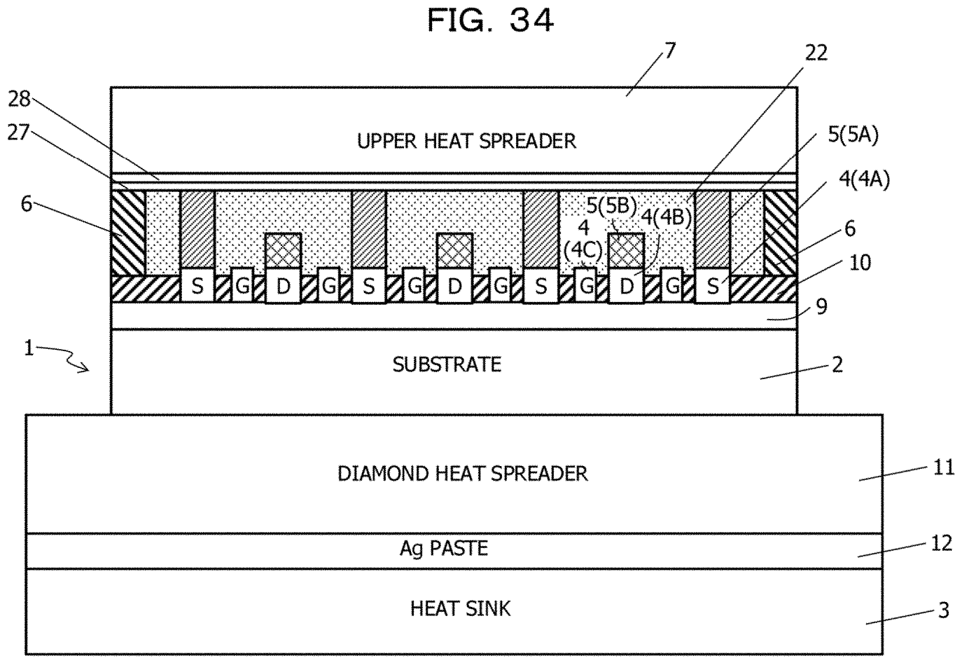

As illustrated in FIGS. 33 and 34, the configuration of the third configuration example is able to be applied to the heat dissipation structure including the diamond heat spreader 11 under the rear surface side of the substrate of the above-described second configuration example. Also in this case, a similar effect may be obtained.

### Second Embodiment

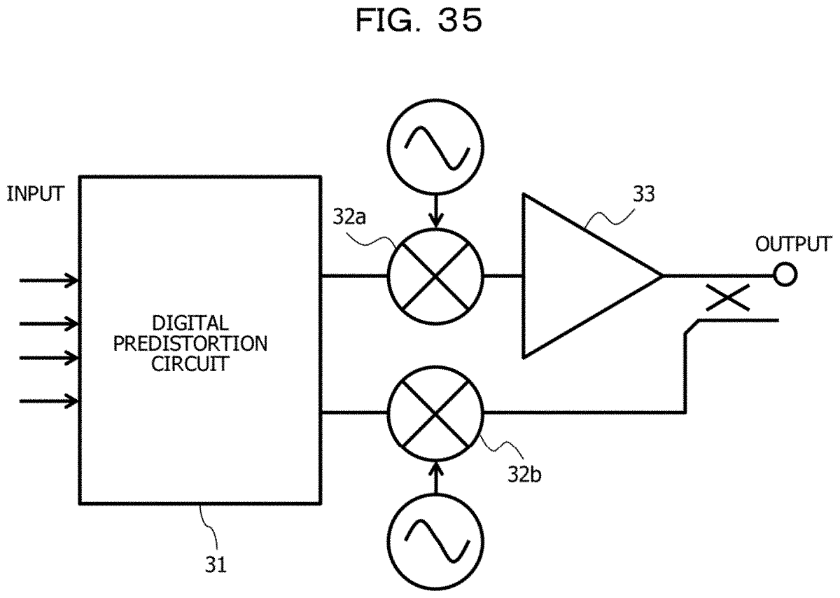

Next, an amplifier according to a second embodiment is described with reference to FIG. 35.

The amplifier according to the present embodiment is a high-frequency amplifier that includes the semiconductor device 1 having the heat dissipation structure according to the above-described embodiment and any of modifications. For example, the amplifier according to the present embodiment is a high-frequency amplifier to which the semiconductor device 1 having the heat dissipation structure according to the above-described embodiment and any of the modifications is applied.

As illustrated in FIG. 35, the high-frequency amplifier is in a configuration in which the high-frequency amplifier includes a digital predistortion circuit 31, mixers 32a and 32b, and a power amplifier 33. The power amplifier 33 is also simply referred to as an amplifier.

The digital predistortion circuit 31 compensates for nonlinear distortion of an input signal.

The mixers 32a and 32b mix the input signal the nonlinear distortion of which has been compensated for with an alternating-current signal.

The power amplifier 33 amplifies the input signal mixed with the alternating-current signal and includes the semiconductor device (including the HEMT) 1 according to the above-described embodiment and any of the modifications.

The configuration illustrated in FIG. 35 permits a signal on the output side to be mixed with an alternating-current signal in the mixer 32b and transmitted to the digital predistortion circuit 31 by, for example, switching a switch.

In the amplifier according to the present embodiment, the semiconductor device (including HEMT) 1 according to the above-described embodiment and any of the modifications is applied to the power amplifier 33. Accordingly, a highly reliable high-frequency amplifier may be realized. Thus, system devices such as communication devices, radars, sensors, and radio jammers with high reliability may be provided.

[Other]

The present disclosure is not limited to the configurations described for each of the above-described embodiments and modifications. Various modifications may be made without departing from the spirit of the present disclosure.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A heat dissipation structure for a semiconductor device, the structure comprising:
a heat sink provided under a rear surface side of a substrate included in a semiconductor device; and
a front heat spreader coupled to metal wiring provided over an electrode disposed on a front surface side of the semiconductor device and a metal unit provided at least partially over an outer peripheral portion of the front surface side of the semiconductor device.

2. The heat dissipation structure according to claim 1, wherein the metal unit is provided over a first part and a second part opposite the first part of the outer peripheral portion of the front surface side of the semiconductor device.

3. The heat dissipation structure according to claim 1, wherein
thermal conductivity of the front heat spreader is 200 W/mK or greater.

4. The heat dissipation structure according to claim 1, wherein
the front heat spreader is formed of a material selected from the group consisting of CuMo, CuW, Al, GaN, Cu, Au, Ag, AlN, SiC, graphite, and diamond.

5. The heat dissipation structure according to claim 1, wherein
a width of the metal unit is 10 μm or greater.

6. The heat dissipation structure according to claim 1, wherein
the electrode is a source electrode, and wherein
the metal wiring is source wiring provided over the source electrode.

7. The heat dissipation structure according to claim 1, wherein
the metal wiring and the metal unit are formed of an identical type of metal.

8. The heat dissipation structure according to claim 1, the structure further comprising:
a diamond heat spreader provided between the substrate and the heat sink.

9. An amplifier comprising:
the semiconductor device that includes the heat dissipation structure for a semiconductor device according to claim 1.

10. A method of manufacturing a heat dissipation structure for a semiconductor device, the method comprising:
providing a heat sink under a rear surface side of a substrate included in a semiconductor device; and
providing a front heat spreader so as to be coupled to metal wiring provided over an electrode disposed on a front surface side of the semiconductor device and a metal unit provided at least partially over an outer peripheral portion of the front surface side of the semiconductor device.

11. The method according to claim 10, wherein
the front heat spreader is coupled to the metal wiring and the metal unit by room-temperature joining in the providing of the front heat spreader.

12. The method according to claim 10, further comprising:
forming the metal wiring and the metal unit before the providing of the front heat spreader is performed; and
aligning the metal wiring and the metal unit in a height direction before the providing of the front heat spreader is performed.

13. The method according to claim 10, further comprising:
forming the metal wiring and the metal unit before the providing of the front heat spreader is performed; and
aligning the metal wiring and the metal unit in a height direction by grinding or polishing the metal wiring or the metal unit before the providing of the front heat spreader is performed.

14. The method according to claim 12, wherein
the metal wiring and the metal unit are simultaneously formed in the forming of the metal wiring and the metal unit.
